(19) United States
(12) Patent Application Publication
(10) Pub. No.: US 2025/0366339 A1
(43) Pub. Date: Nov. 27, 2025

(54) DISPLAY DEVICE AND METHOD OF MANUFACTURING THE SAME

(71) Applicant: Samsung Display Co., LTD., Yongin-si (KR)

(72) Inventors: Keun Woo PARK, Yongin-si (KR); Jae Cheol PARK, Yongin-si (KR); Gak Seok LEE, Yongin-si (KR)

(21) Appl. No.: 19/045,802

(22) Filed: Feb. 5, 2025

(30) Foreign Application Priority Data
May 24, 2024 (KR) 10-2024-0067826

(51) Int. Cl. H10K 59/38; H10K 59/12; H10K 59/127; H10K 59/80

(52) U.S. Cl. CPC H10K 59/38; H10K 59/1201; H10K 59/127; H10K 59/873; H10K 59/877; H10K 59/878; H10K 59/8792

(57) ABSTRACT

A display device includes a first substrate, and a second substrate facing the first substrate. The first substrate includes a first supporting substrate, which includes emission areas arranged in parallel and a non-emission area between the emission areas, an element layer, which is disposed on the first supporting substrate and includes light-emitting elements disposed in the emission areas, an encapsulation layer, which is disposed on the element layer, and a color conversion layer, which is disposed on the encapsulation layer and converts a wavelength range of light emitted from some of the light-emitting elements. The color conversion layer includes light recycling components, which are disposed in parts of the non-emission area.

This application claims priority to Korean Patent Application No. 10-2024-0067826, filed on May 24, 2024, and all the benefits accruing therefrom under 35 U.S.C. § 119, the content of which in its entirety is herein incorporated by reference.

### BACKGROUND

### 1. Field

The disclosure relates to a display device and a method of manufacturing the same.

### 2. Description of the Related Art

As the information society develops, the demand for display devices to show images is increasing in various forms. For example, display devices are applied to various electronic devices such as smartphones, digital cameras, laptop computers, navigations, and smart televisions.

The display devices may be flat display devices such as a liquid crystal display (“LCD”) device, a field emission display (“FED”) device, or a light-emitting display device. Here, the light-emitting display device may include an organic light-emitting display device that includes organic light-emitting elements, an inorganic light-emitting display device that includes inorganic light-emitting elements such as an inorganic semiconductor, and a micro-light-emitting display device that includes micro-light-emitting elements.

The organic light-emitting display device displays an image using light-emitting elements each containing a light-emitting layer of an organic light-emitting material. Since the organic light-emitting display device implements image display using self-luminous elements, it may have relatively superior performance in power consumption, response speed, luminous efficiency, brightness, and wide viewing angle compared to other display devices.

The display surface of a display device where light is emitted may include a display area where an image is displayed and a non-display area around the display area. In the display area, emission areas that emit light with respective brightness and color may be arranged.

### SUMMARY

The display device may include a color conversion layer that converts or transmits light emitted from at least some of the light-emitting elements into light of a different wavelength band.

The color conversion layer may include an ink material that converts the wavelength band of light.

The process of providing the color conversion layer may include an ink ejection process that partially ejects an ink material into ink ejection areas overlapping with at least some of the emission areas.

However, during the ink ejection process, due to the margin of the ejection device, there is a limit in reducing the width of the ink ejection areas. This may limit the relatively high resolution of the display device.

Features of the disclosure provide a display device that may be advantageous for achieving a relatively high resolution and a method for manufacturing the display device.

However, features of the disclosure are not restricted to those set forth herein. The above and other features of the disclosure will become more apparent to one of ordinary skill in the art to which the disclosure pertains by referencing the detailed description of the disclosure given below.

In an embodiment of the disclosure, there is provided a display device which includes a first substrate, and a second substrate facing the first substrate. The first substrate includes a first supporting substrate, which includes emission areas arranged in parallel and a non-emission area between the emission areas, an element layer, which is disposed on the first supporting substrate and includes light-emitting elements disposed in the emission areas, an encapsulation layer, which is disposed on the element layer, and a color conversion layer, which is disposed on the encapsulation layer and converts a wavelength range of light emitted from some of the light-emitting elements. The color conversion layer includes light recycling components, which are disposed in parts of the non-emission area.

In an embodiment, the emission areas may include first emission areas, which emit light in a first wavelength range, second emission areas, which emit light in a second wavelength range lower than the first wavelength range, and third emission areas, which emit light in a third wavelength range lower than the second wavelength range. The non-emission area may include first margin areas, which are connected to parts of the first emission areas, and second margin areas, which are connected to parts of the second emission areas. The light-emitting elements may emit light in a fourth wavelength range lower than the third wavelength range. The color conversion layer may include first color conversion sections, which are disposed in the first emission areas and the first margin areas and convert light in the fourth wavelength range into light in the first wavelength range, second color conversion sections, which are disposed in the second emission areas and the second margin areas and convert light in the fourth wavelength range into light in the second wavelength range, light transmission sections, which are disposed in the third emission areas and transmit and scatter light in the fourth wavelength range, and partition sections, which are disposed between the first color conversion sections, the second color conversion sections, and the light transmission sections. The light recycling components may be disposed in the first margin areas and the second margin areas.

In an embodiment, the partition sections may include first partition walls, which are disposed between the first color conversion sections, the second color conversion sections, and the light transmission sections, reflective walls, which cover sides of the first partition walls and reflect light, and second partition walls, which are disposed on the first partition walls and have hydrophobic properties.

In an embodiment, the second substrate may include a second supporting substrate, which faces the first substrate and includes the emission areas and the non-emission area, a color filter layer, which is disposed on one surface of the second supporting substrate, and a filter capping layer, which covers the color filter layer. The color filter layer may include first filter sections, which are disposed in the first emission areas and transmit light in the first wavelength range, second filter sections, which are disposed in the second emission areas and transmit light in the second wavelength range, third filter sections, which are disposed in the third emission areas and transmit light in the third wavelength range, and a light-blocking section, which is disposed in the non-emission area and blocks light. The light recycling components may overlap with the light-blocking section.

In an embodiment, the display device may further include spacers disposed between the first substrate and the second substrate, and a filling layer disposed between the first and second substrates. The first substrate may further includes a color conversion capping layer, which covers the color conversion layer. The spacers and the filling layer may be disposed between the color conversion capping layer and the filter capping layer. The spacers may overlap with one or more of the first margin areas and the second margin areas.

In an embodiment, the light recycling components may include a reflective layer, which is disposed on the first color conversion sections in the first margin areas and on the second color conversion sections in the second margin areas and reflects light.

In an embodiment, the light recycling components may include scattering sections, which are disposed on the first color conversion sections in the first margin areas and on the second color conversion sections in the second margin areas and scatter light. The scattering sections may overlap with parts of the partition sections between the first color conversion sections and the second color conversion sections. The scattering sections may include a base resin, which have light transmission properties, and scattering particles, which are dispersed in the base resin.

In an embodiment, the light transmission sections may be provided along with the scattering sections and include the base resin and the scattering particles.

In an embodiment, the light recycling components may further include an additional reflective layer, which is disposed on the scattering sections and reflect light.

In an embodiment, the light recycling components may include an extended reflective layer, which extends from the reflective walls and is disposed on the encapsulation layer.

In an embodiment, the first substrate may further include a circuit layer disposed on the first supporting substrate and including emissive pixel drivers electrically connected to the light-emitting elements. The element layer may be disposed on the circuit layer. The element layer may include anode electrodes, which are disposed in the emission areas, a pixel-defining layer, which is disposed in the non-emission area and covers edges of the anode electrodes, light-emitting layers, which are disposed on the anode electrodes and the pixel-defining layer, and a cathode electrode, which is disposed on the light-emitting layers. Each of the light-emitting elements may include a structure in which the light-emitting layers are interposed between the anode electrodes and the cathode electrode that face each other.

In an embodiment of the disclosure, there is provided a method of manufacturing a display device, the method includes preparing a first substrate, preparing a second substrate, disposing a filling layer on the first and second substrates, and bonding the first substrate to the second substrate. The preparing the first substrate includes preparing a first supporting substrate, which includes emission areas arranged in parallel and a non-emission area between the emission areas, disposing a circuit layer on the first supporting substrate, disposing an element layer, which includes light-emitting elements in the emission areas, on the circuit layer, disposing an encapsulation layer on the element layer, disposing a color conversion layer on the encapsulation layer, and disposing a color conversion capping layer, which covers the color conversion layer.

After the disposing the color conversion layer, the color conversion layer includes light recycling components, which are disposed in parts of the non-emission area.

In an embodiment, in the preparing the first supporting substrate, the emission areas may include first emission areas, which emit light in a first wavelength range, second emission areas, which emit light in a second wavelength range lower than the first wavelength range, and third emission areas, which emit light in a third wavelength range lower than the second wavelength range, and the non-emission area includes first margin areas, which are connected to parts of the first emission areas, and second margin areas, which are connected to parts of the second emission areas. In the disposing the element layer, the light-emitting elements may emit light in a fourth wavelength range lower than the third wavelength range. The disposing the color conversion layer may include disposing partition sections on the entirety of the non-emission area except for the first margin areas and the second margin areas, disposing first color conversion sections, which convert light in the fourth wavelength range into light in the first wavelength range, on the first emission areas and the first margin areas, disposing second color conversion sections, which convert light in the fourth wavelength range into light in the second wavelength range, on the second emission areas and the second margin areas, and disposing light transmission sections, which transmit and scatter light in the fourth wavelength range, on the third emission areas.

In an embodiment, after the disposing the light transmission sections, the partition sections may be disposed between the first color conversion sections, the second color conversion sections, and the light transmission sections. The disposing the partition sections may include disposing first partition walls on the entirety of the non-emission area except for the first margin areas and the second margin areas, disposing reflective walls, which reflect light, on sides of the first partition walls, and disposing second partition walls, which have hydrophobic properties, on at least parts of top surfaces of the first partition walls.

In an embodiment, in the disposing the reflective walls, an extended reflective layer, which extends from the reflective walls, may be further disposed in the first margin areas and the second margin areas. The light recycling components include the extended reflective layer.

In an embodiment, the preparing the second substrate may include preparing a second supporting substrate, which includes the emission areas and the non-emission area, disposing a color filter layer on one surface of the second supporting substrate, and disposing a filter capping layer covering the color filter layer. The disposing the color filter layer may include disposing second filter sections, which transmit light in the second wavelength range, in the second emission areas and the non-emission area, disposing first filter sections, which transmit light in the first wavelength range, in the first emission areas and the non-emission area, and disposing third filter sections, which transmit light in the third wavelength range, in the third emission areas and the non-emission area. After the disposing the color filter layer, the color filter layer may include a light-blocking section, which has a structure in which the first filter sections, the second filter sections, and the third filter sections overlap with one another. After the bonding the first and second substrates, the light recycling components may overlap with the light-blocking section.

In an embodiment, the preparing the second substrate may further include disposing spacers, which are spaced apart from one another, on the filter capping layer. After the operation of bonding the first substrate to the second substrate, the spacers and the filling layer may be disposed between the color conversion capping layer and the filter capping layer. The spacers may overlap with one or more of the first margin areas and the second margin areas.

In an embodiment, the disposing the color conversion layer may further include disposing a reflective layer, which reflects light, on the first color conversion sections in the first margin areas and on the second color conversion sections in the second margin areas, after the disposing the light transmission sections. The light recycling components may include the reflective layer.

In an embodiment, in the disposing the light transmission sections, scattering sections, which scatter light, may be further disposed on the first color conversion sections in the first margin areas and on the second color conversion sections in the second margin areas. The scattering sections may overlap with parts of the partition sections between the first color conversion sections and the second color conversion sections. The light transmission sections and the scattering sections may each include a base resin, which have light transmission properties, and scattering particles, which are dispersed in the base resin. The light recycling components may include the scattering sections.

In an embodiment, the disposing the color conversion layer may further include disposing a reflective layer, which reflects light, on the scattering sections, after the disposing the light transmission sections. The light recycling components may further include the reflective layer.

In an embodiment of the disclosure, a display device includes a first substrate and a second substrate that face each other. The first substrate includes a first supporting substrate, which includes emission areas arranged in parallel and a non-emission area between the emission areas, an element layer, which is disposed on the first supporting substrate and includes light-emitting elements disposed in the emission areas, an encapsulation layer, which is disposed on the element layer, and a color conversion layer, which is disposed on the encapsulation layer and converts a wavelength range of light emitted from some of the light-emitting elements. The color conversion layer includes light recycling components, which are disposed in parts of the non-emission area.

In an embodiment, the color conversion layer may include first color conversion sections, which are disposed in the first emission areas and the first margin areas, second color conversion sections, which are disposed in the second emission areas and the second margin areas, and light transmission sections, which are disposed in the third emission areas.

As such, since the first color conversion sections are disposed not only in the first emission areas but also in the first margin areas of the non-emission area, the width of the first emission areas may be smaller than the margin of an ejection device. Additionally, since the second color conversion sections are disposed not only in the second emission areas but also in the second margin areas of the non-emission area, the width of the second emission areas may be smaller than the margin of the ejection device.

Therefore, regardless of the margin of the ejection device, the widths of the emission areas may be reduced, which may be advantageous for achieving a relatively high resolution in the display device.

By the embodiments of the disclosure, the light recycling components may be disposed in the first margin areas and the second margin areas.

In this manner, due to the light recycling components disposed in the first margin areas, at least some of the light incident into the first margin areas may be reflected and introduced into the first emission areas, and then emitted through the first emission areas. That is, the light incident into the first margin areas is not entirely extinguished or absorbed in the first margin areas but may be partially recycled by the light recycling components in the first margin areas.

Furthermore, due to the light recycling components disposed in the second margin areas, at least some of the light incident into the second margin areas may be reflected and introduced into the second emission areas, and then emitted through the second emission areas. That is, the light incident into the second margin areas is not entirely extinguished or absorbed in the second margin areas but may be partially recycled by the light recycling components in the second margin areas.

Therefore, as the light in both the first margin areas and the second margin areas is recycled by the light recycling components, the light emission efficiency of both the first emission areas and the second emission areas may be improved. As a result, the brightness of the display device may be enhanced.

It should be noted that the effects of the disclosure are not limited to those described above, and other effects of the disclosure will be apparent from the following description.

### BRIEF DESCRIPTION OF THE DRAWINGS

The above and other advantages and features of the disclosure will become more apparent by describing in detail embodiments thereof with reference to the attached drawings, in which:

FIG. 1 is a plan view illustrating an embodiment of a display device according to the disclosure;

FIG. 2 is a cross-sectional view taken along line A-A′ of FIG. 1;

FIG. 3 is a plan view illustrating a display area and circuit layer in portion B of FIG. 1;

FIG. 4 is a block diagram illustrating a circuit layer in portion B of FIG. 1;

FIG. 5 is an equivalent circuit diagram illustrating emissive pixel drivers of FIG. 4;

FIG. 6 is a plan view illustrating a color conversion layer in portion B of FIG. 1;

FIG. 7 is a plan view illustrating a color filter layer in portion B of FIG. 1;

FIG. 8 is a cross-sectional view taken along line C-C′ of FIGS. 6 and 7;

FIG. 9 is a cross-sectional view taken along line D-D′ of FIGS. 6 and 7;

FIG. 10 is a plan view illustrating an embodiment of a color conversion layer, in portion B of FIG. 1, of a display device according to the disclosure;

FIGS. 11, 12, 13, and 14 are cross-sectional views taken along line E-E′ of FIG. 10;

FIG. 15 is a flowchart illustrating an embodiment of a method of manufacturing a display device according to the disclosure;

FIG. 16 is a flowchart illustrating the operation of preparing a first substrate of FIG. 15;

FIG. 17 is a flowchart illustrating the operation of disposing a color conversion layer of FIG. 16;

FIGS. 18, 19, 20, 21, 22, 23, 24, 25, 26, 27, 28, 29, 30, 31, and 32 are cross-sectional views illustrating some of the operations depicted in FIGS. 15, 16, and 17, in the embodiment of FIG. 11; and

FIGS. 33 and 34 are cross-sectional views illustrating some of the operations depicted in FIG. 17, in the embodiment of FIG. 14.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure. In the accompanying drawing figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it may be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

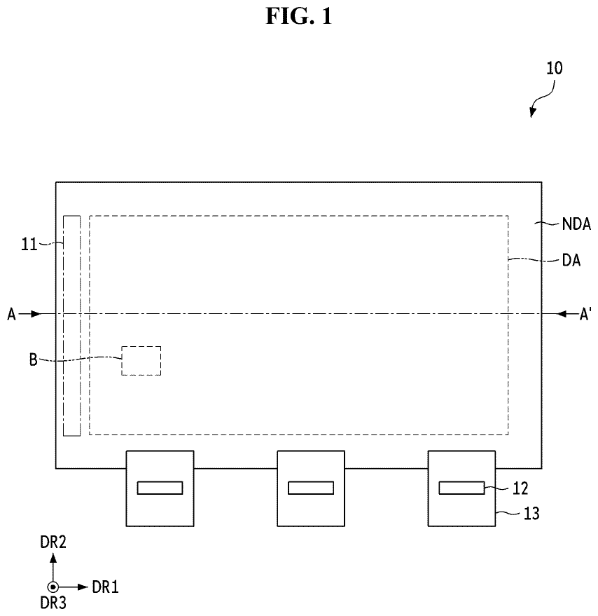

FIG. 1 is a plan view illustrating an embodiment of a display device according to the

### DISCLOSURE

Referring to FIG. 1, a display device 10, which is a device for displaying a moving or still image, may be used as a display screen for various products such as mobile phones, smart phones, tablet personal computers (“PC”), smart watches, watch phones, portable communication terminals, electronic notepads, electronic books, portable multimedia players (“PMPs”), navigation devices, and Ultra Mobile PCs (“UMPCs”), as well as televisions, laptops, monitors, billboards, and Internet of Things (“IoT”) devices.

The display device 10 may be a light-emitting display device such as an organic light-emitting display device using organic light-emitting diodes (“OLEDs”), a quantum dot light-emitting display device including a quantum dot light-emitting layer, an inorganic light-emitting display device including inorganic semiconductors, or a micro-light-emitting diode (“micro-LED”) display device or nano-LED display device. The display device 10 will hereinafter be described mainly as being an organic light-emitting display device, but the disclosure is not limited thereto. In an alternative embodiment, the disclosure may also be applicable to a display device including an organic insulating material, an organic light-emitting material, and a metallic material.

The display device 10 may be formed flat, but the disclosure is not limited thereto. In an embodiment, the display device 10 may include curved sections at its left and right ends with uniform or varying curvature, for example. Additionally, the display device 10 may be flexible such as bendable, curvable, foldable, or rollable.

In an embodiment, the display device 10 may be an organic light-emitting display device.

As illustrated in FIG. 1, the display device 10 may include a quadrangular shape, e.g., rectangular shape, but the disclosure is not limited thereto. That is, the shape of the display device 10 is not limited to that illustrated in FIG. 1. In other words, the display device 10 may have a polygonal or circular shape other than a rectangular surface. In an alternative embodiment, at least part of the display device 10 may be able to transition from a flat form to a bent, curved, folded, or rolled form.

One surface of the display device 10 may include a display area DA from which light for displaying an image is emitted, and a non-display area NDA which surrounds the display area DA.

The display area DA may account for most of the surface of the display device 10.

The non-display area NDA may be in the form of a frame surrounding the display area DA without emitting light for displaying an image. In an embodiment, the non-display area NDA may be maintained in a particular color such as black, for example.

The display device 10 may include drivers 11 and 12 that deliver signals, voltages, or power to emissive pixel drivers EPD disposed in the display area DA. In the disclosure, each of the drivers may be a driving circuitry.

A driver 11, which may be implemented with relatively simple circuitry, may be disposed in the non-display area NDA.

Other drivers 12 may be provided as integrated circuit (“IC”) chips and may be disposed (e.g., mounted) on circuit boards 13 electrically connected to pads in the non-display area NDA. In an alternative embodiment, the drivers 12 may be disposed (e.g., mounted) on the pads in the non-display area NDA.

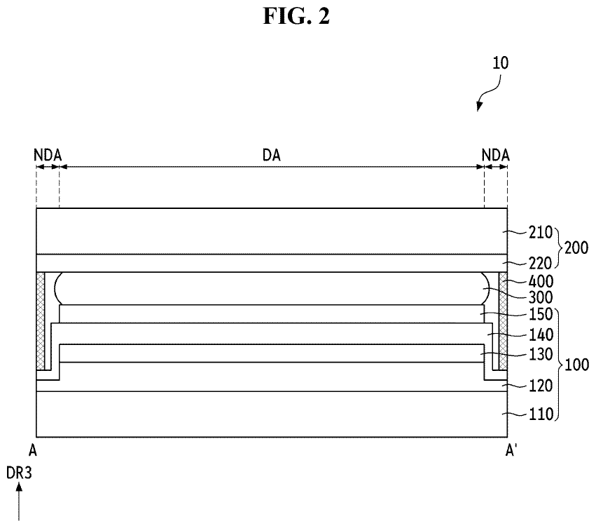

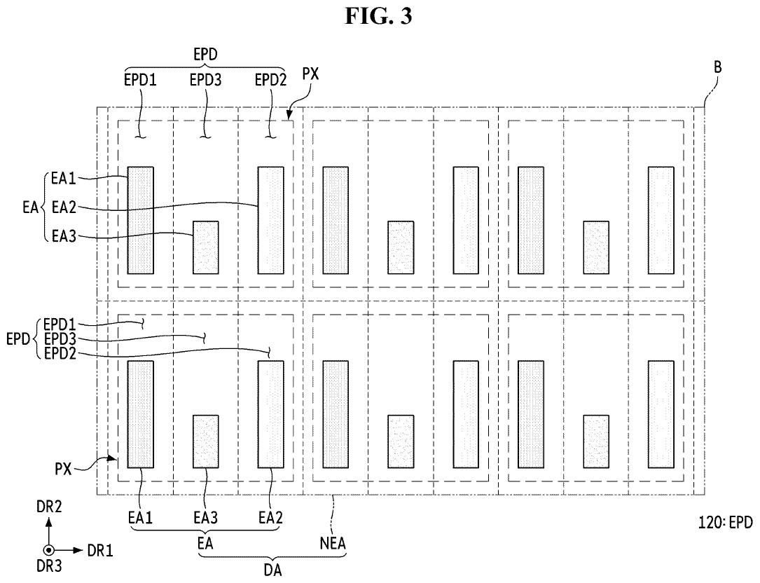

FIG. 2 is a cross-sectional view taken along line A-A′ of FIG. 1. FIG. 3 is a plan view illustrating the display area and circuit layer in portion B of FIG. 1.

Referring to FIG. 2, the display device 10 may include a first substrate 100 and a second substrate 200, which faces the first substrate 100.

The display device 10 may further include a filling layer 300, which is disposed between the first and second substrates 100 and 200. The filling layer 300 may be disposed at least in the display area DA and may fill the space between the first and second substrates 100 and 200.

The display device 10 may also include a sealing layer 400, which is disposed in the non-display area NDA and bonds the first and second substrates 100 and 200 together.

The first substrate 100 may include a first supporting substrate 110, an element layer 130, which is disposed on the first supporting substrate 110, an encapsulation layer 140, which is disposed on the element layer 130, and a color conversion layer 150, which is disposed on the encapsulation layer 140.

The first substrate 100 may further include a circuit layer 120, which is disposed on the first supporting substrate 110. The element layer 130 may be disposed on the circuit layer 120.

The first supporting substrate 110 includes a display area DA where light for displaying an image is emitted and a non-display area NDA which surrounds the display area DA and does not emit light.

Referring to FIG. 3, the display area DA may include emission areas EA where light is emitted and a non-emission area NEA between the emission areas EA.

The emission areas EA may include first emission areas EA1, which emit light in a first wavelength range, second emission areas EA2, which emit light in a second wavelength range lower than the first wavelength range, and third emission areas EA3, which emit light in a third wavelength range lower than the second wavelength range.

In an embodiment, the first wavelength range may be about 600 nanometers (nm) to about 750 nm, and the light in the first wavelength range may be red light, for example. The second wavelength range may be about 480 nm to about 560 nm, and the light in the second wavelength range may be green light. The third wavelength range may be about 370 nm to about 460 nm, and the light in the third wavelength range may be blue light.

Accordingly, a unit pixel PX that displays white light may be provided by one or more first emission areas EA1, one or more second emission areas EA2, and one or more third emission areas EA3 that are next (adjacent) to each other among the emission areas EA.

In an embodiment, the first emission areas EA1, the second emission areas EA2, and the third emission areas EA3 may each be arranged in parallel in a second direction DR2.

Additionally, the third emission areas EA3 may be disposed between the first emission areas EA1 and the second emission areas EA2 in a first direction DR1.

Each of the emission areas EA may be arranged in one of the following shapes quadrangular (e.g., rectangular), triangular, rhomboid, square, trapezoidal, circular, and oval shapes.

In an embodiment, the third emission areas EA3 may have a smaller width than those of the first emission areas EA1 and the second emission areas EA2. Thus, in the second direction DR2, the spacing between the third emission areas EA3 may be greater than the spacing between the first emission areas EA1 and the spacing between the second emission areas EA2.

The circuit layer 120 of the first substrate 100 may include the emissive pixel drivers EPD, which are arranged in parallel to one another.

The emissive pixel drivers EPD may include first emissive pixel drivers EPD1, which are electrically connected to light-emitting elements LE of the first emission areas EA1, second emissive pixel drivers EPD2, which are electrically connected to light-emitting elements LE of the second emission areas EA2, and third emissive pixel drivers EPD3, which are electrically connected to light-emitting elements LE of the third emission areas EA3.

As illustrated in FIG. 2, the element layer 130 of the first substrate 100 may include light-emitting elements LE, which are disposed in the emission areas EA.

The light-emitting elements LE may emit light in a fourth wavelength range lower than the third wavelength range.

The light-emitting elements LE of the element layer 130 may be electrically connected to the emissive pixel drivers EPD of the circuit layer 120.

The encapsulation layer 140 may include at least two inorganic insulating layers that include an inorganic insulating material and at least one organic insulating layer that includes an organic insulating material and is disposed between the inorganic insulating layers.

The encapsulation layer 140 may prevent defects in the circuit layer 120 or the element layer 130 caused by foreign substances, and may prevent the penetration of oxygen or moisture into the circuit layer 120 or the element layer 130.

The color conversion layer 150 may convert the wavelength range of light emitted from some of the light-emitting elements LE of the element layer 130.

That is, the color conversion layer 150 may convert the light emitted from the light-emitting elements LE of the first emission areas EA1 from the fourth wavelength range to the first wavelength range, may convert the light emitted from the light-emitting elements LE of the second emission areas EA2 from the fourth wavelength range to the second wavelength range, and may transmit and scatter the light emitted from the light-emitting elements LE of the third emission areas EA3.

The second substrate 200 may include a second supporting substrate 210, which faces the first supporting substrate 110 and includes the emission areas EA and the non-emission area NEA, and a color filter layer 220, which is disposed on one surface of the second supporting substrate 210.

The color filter layer 220 may transmit light of particular wavelength ranges through each of the emission areas EA from the light emitted from the color conversion layer 150 of the first substrate 100.

That is, the color filter layer 220 may transmit light in the first wavelength range through the first emission areas EA1, may transmit light in the second wavelength range through the second emission areas EA2, and may transmit light in the third wavelength range through the third emission areas EA3.

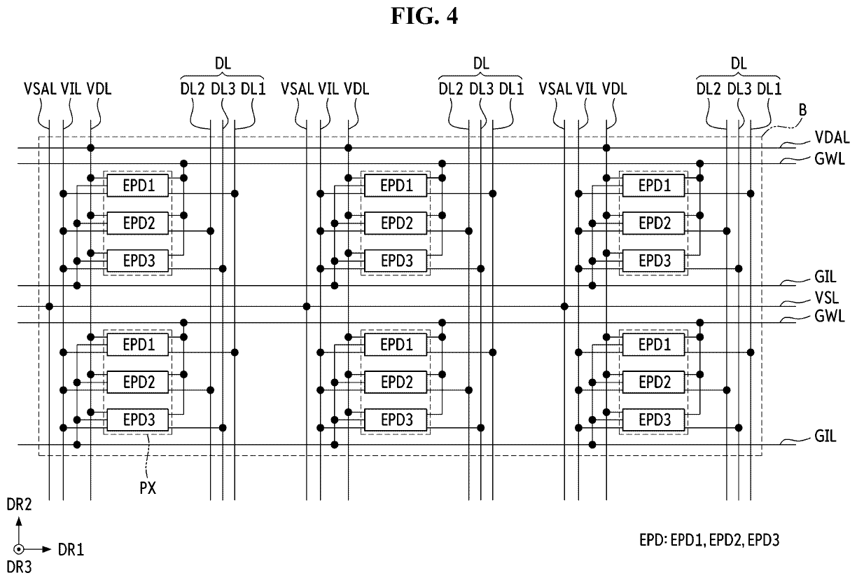

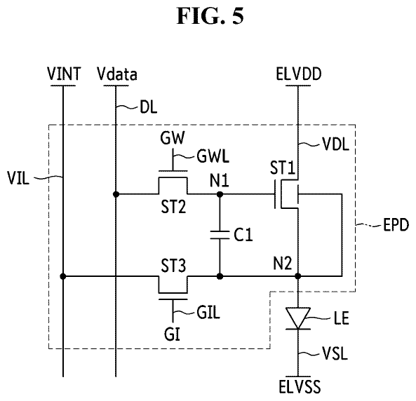

FIG. 4 is a block diagram illustrating the circuit layer in portion B of FIG. 1. FIG. 5 is an equivalent circuit diagram illustrating the emissive pixel drivers of FIG. 4.

Referring to FIG. 4, the circuit layer 120 of the first substrate 100 in the display device 10 may include the emissive pixel drivers EPD, which are electrically connected to the light-emitting elements LE of the emission areas EA.

The emissive pixel drivers EPD may include the first emissive pixel drivers EPD1, which are electrically connected to the light-emitting elements LE of the first emission areas EA1, the second emissive pixel drivers EPD2, which are electrically connected to the light-emitting elements LE of the second emission areas EA2, and the third emissive pixel drivers EPD3, which are electrically connected to the light-emitting elements LE of the third emission areas EA3.

The circuit layer 120 may further include scan write lines GWL for delivering scan write signals GW to the emissive pixel drivers EPD, scan initialization lines GIL for delivering scan initialization signals GI to the emissive pixel drivers EPD, data lines DL for delivering data signals Vdata to the emissive pixel drivers EPD, initialization voltage lines VIL for delivering initialization voltages VINT to the emissive pixel drivers EPD, first power supply lines VDL for delivering a first power supply ELVDD to the emissive pixel drivers EPD, and second power supply lines VSL for delivering a second power supply ELVSS to the light-emitting elements LE.

The circuit layer 120 may also include first additional power supply lines VDAL for reducing the resistance of the first power supply lines VDL, and second additional power supply lines VSAL for reducing the resistance of the second power supply lines VSL.

The first additional power supply lines VDAL may extend in a direction intersecting the first power supply lines VDL and may be electrically connected to the first power supply lines VDL.

The second additional power supply lines VSAL may extend in a direction intersecting the second power supply lines VSL and may be electrically connected to the second power supply lines VSL.

The data lines DL may include first data lines DL1 for delivering the data signals Vdata to the first emissive pixel drivers EPD1, second data lines DL2 for delivering the data signals Vdata to the second emissive pixel drivers EPD2, and third data lines DL3 for delivering the data signals Vdata to the third emissive pixel drivers EPD3.

Referring to FIG. 5, an emissive pixel driver EPD may be electrically connected between a first power supply ELVDD and a light-emitting element LE, and the light-emitting element LE may be electrically connected between the emissive pixel driver EPD and a second power supply ELVSS.

The light-emitting element LE may be (an organic light-emitting diode (“OLED”) that includes an organic light-emitting layer, a quantum dot light-emitting diode (“LED”) that includes a quantum dot light-emitting layer, a micro-LED, or an inorganic LED that includes an inorganic semiconductor.

The second power supply ELVSS may have a lower voltage level than that of the first power supply ELVDD.

That is, an anode electrode of the light-emitting element LE may be electrically connected to the emissive pixel driver EPD, and a cathode electrode of the light-emitting element LE may be electrically connected to the second power supply ELVSS.

The emissive pixel driver EPD may include a first transistor ST1 that generates a driving current for the light-emitting element LE, and one or more transistors (i.e., second and third transistors ST2 and ST3) and at least one capacitor (i.e., a first capacitor C1) that are electrically connected to the first transistor ST1.

The first transistor ST1 may be electrically connected between the first power supply line VDL and the light-emitting element LE.

A first electrode of the first transistor ST1 may be electrically connected to the first power supply line VDL.

A second electrode of the first transistor ST1 may be electrically connected to a second node N2 and the anode electrode of the light-emitting element LE.

A first gate electrode of the first transistor ST1 may be electrically connected to a first node N1 and the second transistor ST2.

A second gate electrode of the first transistor ST1 may be electrically connected to the second node N2.

The second transistor ST2 may be electrically connected between the data line DL and the first node N1.

A gate electrode of the second transistor ST2 may be electrically connected to a scan write line GWL. That is, the second transistor ST2 may be turned on by a scan write signal GW from the scan write line GWL.

When the second transistor ST2 is turned on, a data signal Vdata from a data line DL may be delivered to the first node N1.

Due to the data signal Vdata transmitted to the first node N1, the voltage difference between the gate electrode of the first transistor ST1 and the first electrode of the first transistor ST1, i.e., the gate-source voltage difference, may become the differential voltage between the first power supply ELVDD and the data signal Vdata and may exceed the threshold voltage of the first transistor ST1. Thus, the first transistor ST1 may be turned on, generating a source-drain current between the first and second electrodes of the first transistor ST1 corresponding to the data signal Vdata. The source-drain current of the first transistor ST1 may be supplied as a driving current to the light-emitting element LE.

Thus, since the driving current corresponding to the data signal Vdata is supplied to the light-emitting element LE, the light-emitting element LE may emit light with a brightness corresponding to the data signal Vdata.

The first capacitor C1 may be electrically connected between the first node N1 and the second node N2.

The first capacitor C1 may be charged by the data signal Vdata delivered to the first node N1 through the turned-on second transistor ST2.

Accordingly, the potential of the first node N1 may be maintained for a predetermined period by the voltage charged in the first capacitor C1.

The third transistor ST3 may be electrically connected between an initialization voltage line VIL and the second node N2.

A gate electrode of the third transistor ST3 may be electrically connected to a scan initialization line GIL. That is, the third transistor ST3 may be turned on by a scan initialization signal GI from the scan initialization line GIL.

When the third transistor ST3 is turned on, the potential of the second node N2, i.e., the potential of the anode electrode of the light-emitting element LE, may be initialized to an initialization voltage VINT of an initialization voltage line VIL.

As illustrated in FIG. 5, in an embodiment, the first, second, and third transistors ST1, ST2, and ST3 may be N-type metal-oxide semiconductor field-effect transistors (“MOSFETs”), but the disclosure is not limited thereto. In an alternative embodiment, at least one of the first, second, and third transistors ST1, ST2, and ST3 may be a P-type MOSFET.

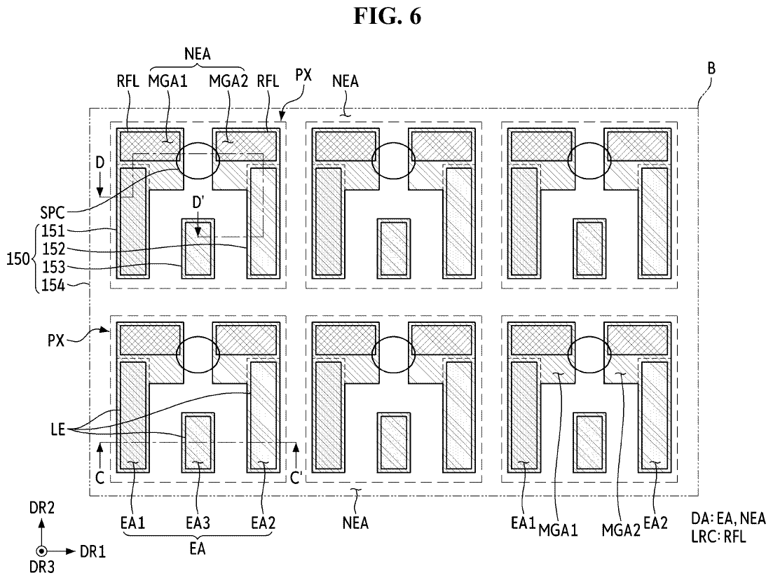

FIG. 6 is a plan view illustrating the color conversion layer in portion B of FIG. 1.

Referring to FIG. 6, the display area DA of the display device 10 may include emission areas EA and a non-emission area NEA, which is a gap area between the emission areas EA.

The emission areas EA may include the first emission areas EA1, which emit light in the first wavelength range, the second emission areas EA2, which emit light in the second wavelength range lower than the first wavelength range, and the third emission areas EA3, which emit light in the third wavelength range lower than the second wavelength range.

The non-emission area NEA may include first margin areas MGA1, which are connected to parts of the first emission areas EA1, and second margin area MGA2, which are connected to parts of the second emission areas EA2.

In an embodiment, the first margin areas MGA1 may extend from parts of the first emission areas EA1 in the first and second directions DR1 and DR2.

Similarly, the second margin areas MGA2 may extend from parts of the second emission areas EA2 in the first and second directions DR1 and DR2.

The first margin areas MGA1 and the second margin areas MGA2 may face each other in the first direction DR1.

The first margin areas MGA1 and the second margin areas MGA2 may have a width corresponding to the margin of an ejection device used in an ink ejection process for arranging the color conversion layer 150.

The color conversion layer 150 in the first substrate 100 of the display device 10 may include first color conversion sections 151, which are disposed in the first emission areas EA1 and the first margin areas MGA1, second color conversion sections 152, which are disposed in the second emission areas EA2 and the second margin areas MGA2, light transmission sections 153, which are disposed in the third emission areas EA3, and partition sections 154, which are disposed between the first color conversion sections 151, the second color conversion sections 152, and the light transmission sections 153.

The first color conversion sections 151 may convert light in the fourth wavelength range emitted from the light-emitting elements LE to the first wavelength range.

The second color conversion sections 152 may convert light in the fourth wavelength range emitted from the light-emitting elements LE to the second wavelength range.

The light transmission sections 153 may transmit and scatter light in the fourth wavelength range emitted from the light-emitting elements LE.

Since the first color conversion sections 151 are disposed in both the first emission areas EA1 and the first margin areas MGA1, the width of the first emission areas EA1 may be reduced regardless of the margin of the ejection device used in the ink ejection process for arranging the first color conversion sections 151.

Similarly, since the second color conversion sections 152 are disposed in both the second emission areas EA2 and the second margin areas MGA2, the width of the second emission areas EA2 may be reduced regardless of the margin of the ejection device used in the ink ejection process for arranging the second color conversion sections 152.

Consequently, the influence of the margin of the ejection device used in the ink ejection process on the width of the emission areas EA may be eliminated, which may be advantageous for achieving a relatively high resolution in the display device 10.

The display device 10 includes light recycling components LRC, which are disposed in parts of the non-emission area NEA.

That is, the light recycling components LRC may be disposed in the first margin areas MGA1 and the second margin areas MGA2.

The light recycling components LRC may reflect at least some of the light introduced into the first margin areas MGA1 and the second margin areas MGA2 back into the first emission areas EA1 and the second emission areas EA2, respectively. Due to the light recycling components LRC, some of the light introduced into the first margin areas MGA1 and the second margin areas MGA2 may be emitted through the first emission areas EA1 and the second emission areas EA2, respectively, instead of being extinguished or absorbed in the non-emission area NEA. That is, since light may be reused, the light emission efficiency may be improved, and consequently, the brightness of the display device 10 may be enhanced.

In an embodiment, the light recycling components LRC may include a reflective layer RFL.

The reflective layer RFL may be disposed in the first margin areas MGA1 and the second margin areas MGA2 and may include a material that reflects light.

The display device 10 may further include spacers SPC, which are disposed between the first and second substrates 100 and 200.

The spacers SPC may overlap with the first margin areas MGA1 and/or the second margin areas MGA2.

In this manner, since the spacers SPC overlap with the light recycling components LRC disposed in the first margin areas MGA1 or the second margin areas MGA2, the gap between the first and second substrates 100 and 200 may be reduced by the thickness of the light recycling components LRC, and as a result, the thickness of the spacers SPC may be reduced.

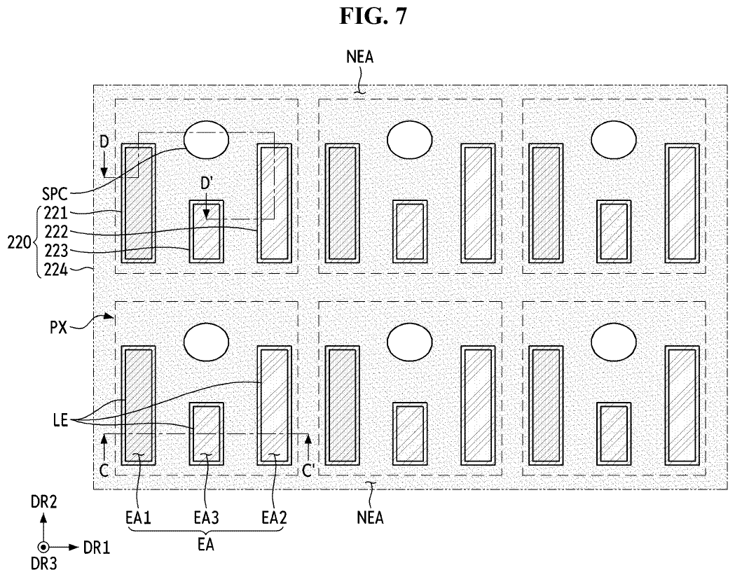

FIG. 7 is a plan view illustrating the color filter layer in portion B of FIG. 1.

Referring to FIG. 7, the color filter layer 220 in the second substrate 200 of the display device 10 may include first filter sections 221, which are disposed in the first emission areas EA1 and transmit light in the first wavelength range, second filter sections 222, which are disposed in the second emission areas EA2 and transmit light in the second wavelength range, third filter sections 223, which are disposed in the third emission areas EA3 and transmit light in the third wavelength range, and a light-blocking section 224, which is disposed in the non-emission area NEA and blocks light.

The spacers SPC may overlap with the light-blocking section 224.

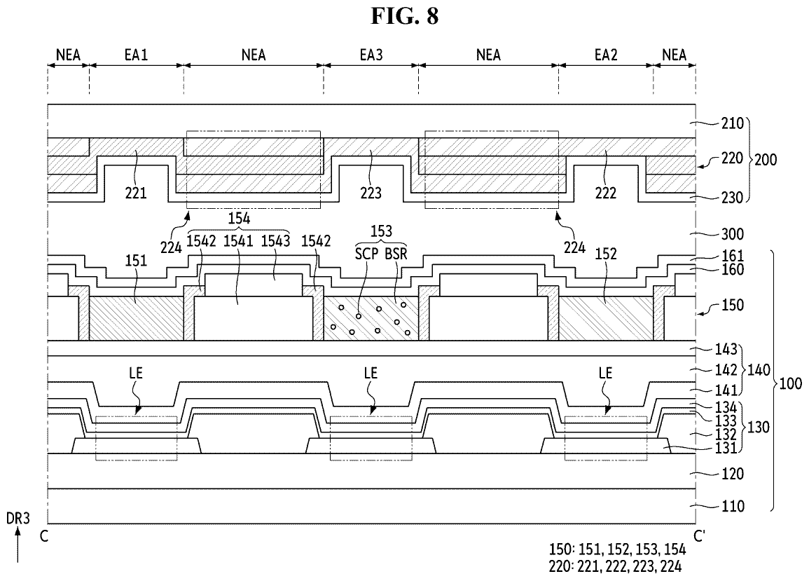

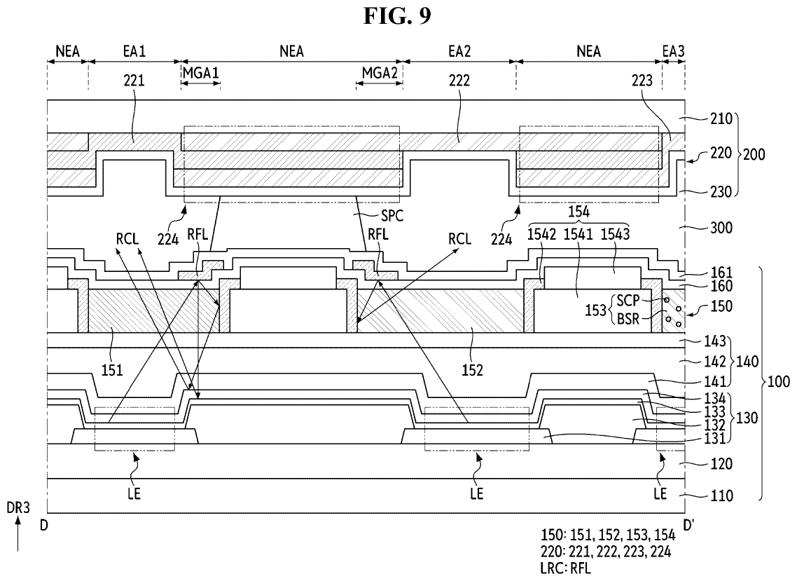

FIG. 8 is a cross-sectional view taken along line C-C′ of FIGS. 6 and 7. FIG. 9 is a cross-sectional view taken along line D-D′ of FIGS. 6 and 7.

Referring to FIGS. 8 and 9, the first substrate 100 of the display device 10 may include the first supporting substrate 110, the circuit layer 120, which is disposed on the first supporting substrate 110, the element layer 130, which is disposed on the circuit layer 120, the encapsulation layer 140, which is disposed on the element layer 130, the color conversion layer 150, which is disposed on the encapsulation layer 140, and a color conversion capping layer 160, which covers the color conversion layer 150.

The element layer 130 includes the light-emitting elements LE, which are disposed in the emission areas EA.

The light-emitting elements LE may have a structure where light-emitting layers 133 are disposed between anode electrodes 131 and a cathode electrode 134, which face the anode electrodes 131.

That is, the element layer 130 may include the anode electrodes 131, which are disposed in the emission areas EA, a pixel-defining layer 132, which is disposed in the non-emission area NEA and covers the edges of the anode electrodes 131, the light-emitting layers 133, which are disposed on the anode electrodes 131 and the pixel-defining layer 132, and the cathode electrode 134, which is disposed on the light-emitting layers 133.

In an alternative embodiment, the light-emitting layers 133 may be disposed in the emission areas EA, respectively.

The encapsulation layer 140, which is disposed on the element layer 130, may include a first encapsulation layer 141, which includes an inorganic insulating material, a second encapsulation layer 142, which is disposed on the first encapsulation layer 141 and includes an organic insulating material, and a third encapsulation layer 143, which is disposed on the second encapsulation layer 142 and includes an inorganic insulating material.

The color conversion layer 150 may include the first color conversion sections 151, which are disposed in the first emission areas EA1, the second color conversion sections 152, which are disposed in the second emission areas EA2, the light transmission sections 153, which are disposed in the third emission areas EA3, and the partition sections 154, which are disposed between the first color conversion sections 151, the second color conversion sections 152, and the light transmission sections 153.

The first color conversion sections 151 may convert light in the fourth wavelength range, emitted from the light-emitting elements LE in the first emission areas EA1, into light in the first wavelength range.

The first color conversion sections 151 may be cured ink substances from a first ink material that includes a base resin and first color conversion particles dispersed in the base resin. The first color conversion particles may convert light in the fourth wavelength range into light in the first wavelength range.

The second color conversion sections 152 may convert light in the fourth wavelength range, emitted from the light-emitting elements LE in the second emission areas EA2, into light in the second wavelength range.

The second color conversion sections 152 may be cured ink substances from a second ink material that includes a base resin and second color conversion particles dispersed in the base resin. The second color conversion particles may convert light in the fourth wavelength range into light in the second wavelength range.

The light transmission sections 153 may transmit and scatter light in the fourth wavelength range, emitted from the light-emitting elements LE in the third emission areas EA3.

The light transmission sections 153 may include a base resin BSR and scattering particles SCP dispersed in the base resin BSR.

The scattering particles SCP may be metal oxide particles or organic particles.

The metal oxide particles may be at least one of titanium oxide (TiO₂), zirconium oxide (ZrO₂), aluminum oxide (Al₂O₃), indium oxide (In₂O₃), zinc oxide (ZnO), or tin oxide (SnO₂).

The organic particles may be acrylic resin or urethane resin.

The first color conversion sections 151 and the second color conversion sections 152 may each further include scattering particles dispersed in the base resin.

The first color conversion particles and the second color conversion particles may each be one or more of quantum dots, quantum rods, and phosphors.

The quantum dots may include or consist of IV-group nanocrystals, II-VI compound nanocrystals, III-V compound nanocrystals, IV-VI nanocrystals, and combinations thereof.

The first color conversion sections 151, the second color conversion sections 152, and the light transmission sections 153 may include the same base resin or different base resins.

As illustrated in FIG. 9, the first color conversion sections 151 may be disposed not only in the first emission areas EA1 but also in the first margin areas MGA1 of the non-emission area NEA.

Similarly, the second color conversion sections 152 may be disposed not only in the second emission areas EA2 but also in the second margin areas MGA2 of the non-emission area NEA.

In this manner, the widths of the first emission areas EA1 and the second emission areas EA2 may not be limited by the margin of the ejection device, which may be advantageous for achieving a relatively high resolution in the display device 10.

As illustrated in FIGS. 8 and 9, the partition sections 154 may surround the first color conversion sections 151, the second color conversion sections 152, and the light transmission sections 153.

The partition sections 154 may include first partition walls 1541, which are disposed between the first color conversion sections 151, the second color conversion sections 152, and the light transmission sections 153, reflective walls 1542, which cover the sides of the first partition walls 1541 and reflect light, and second partition walls 1543, which are disposed on the first partition walls 1541 and have hydrophobic properties.

The first partition walls 1541 may define boundaries between the first color conversion sections 151, the second color conversion sections 152, and the light transmission sections 153. The first partition walls 1541 may include an organic material.

The reflective walls 1542 may include a reflective metal material. The reflective walls 1542 may reflect light directed toward the first partition walls 1541 back into the first color conversion sections 151, the second color conversion sections 152, and the light transmission sections 153.

The reflective walls 1542 may not cover the central portions of the top surfaces of the first partition walls 1541. This may reduce the influx or accumulation of static electricity due to the conductivity of the reflective walls 1542, thereby preventing damage from static electricity.

The second partition wall 1543 may include an organic material with a hydrophobic surface.

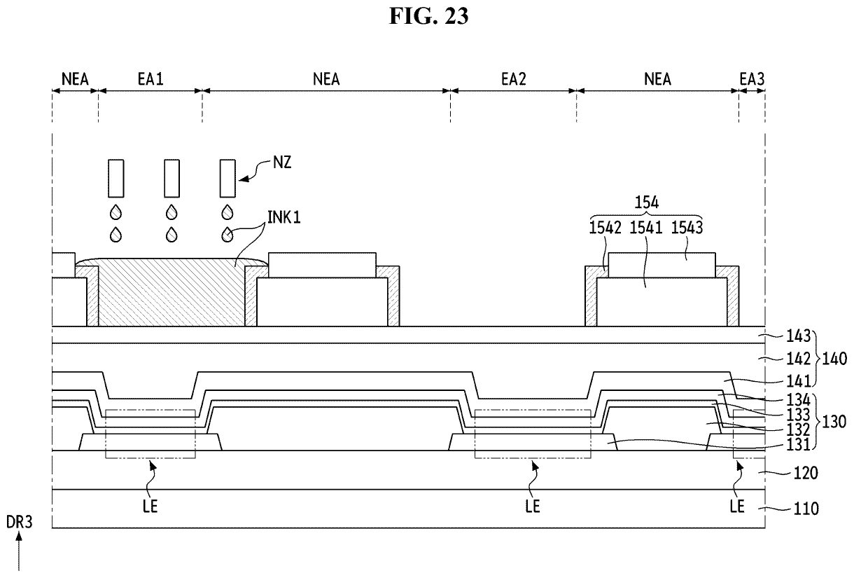

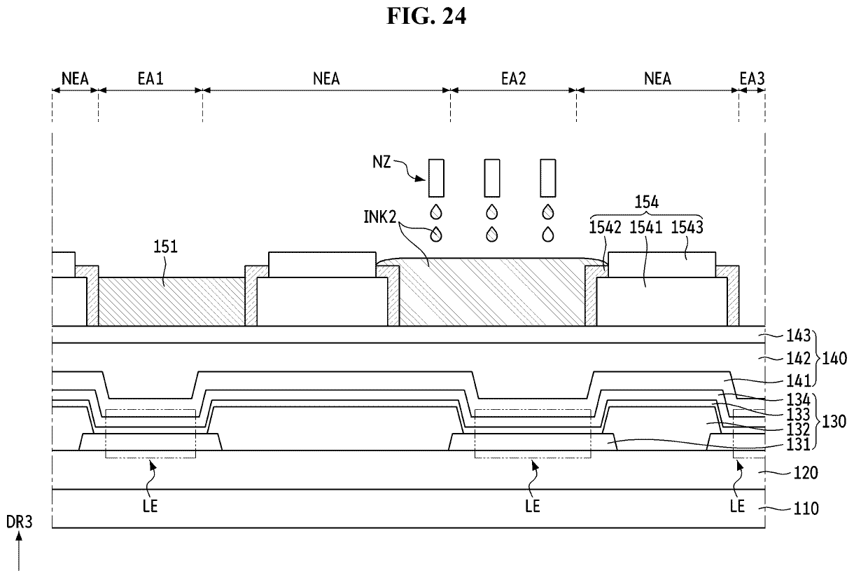

Due to the hydrophobicity of the second partition walls 1543, first and second ink materials INK1 (refer to FIG. 23) and INK2 (refer to FIG. 24) may easily aggregate within the first emission areas EA1 and the second emission areas EA2 during the arrangement of the first color conversion sections 151 and the second color conversion sections 152.

In an embodiment, the second partition walls 1543 may contact the top surfaces of the first partition walls 1541 and may overlap with parts of the reflective walls 1542, for example.

The color conversion capping layer 160, which covers the color conversion layer 150, may include an inorganic insulating material.

The display device 10 may include the light recycling components LRC, which are disposed in the first margin areas MGA1 and the second margin areas MGA2.

As illustrated in FIG. 9, in an embodiment, the light recycling components LRC may include the reflective layer RFL, which is disposed on the first color conversion sections 151 in the first margin areas MGA1 and on the second color conversion sections 152 in the second margin areas MGA2.

The reflective layer RFL may include a reflective metal material.

In an embodiment, the reflective layer RFL may be disposed on the color conversion capping layer 160 and may be covered with an additional capping layer 161, for example. This may help reduce the peeling of the reflective layer RFL.

The second substrate 200 of the display device 10 may include the second supporting substrate 210, the color filter layer 220, which is disposed on one surface of the second supporting substrate 210, and the filter capping layer 230, which covers the color filter layer 220.

In the direction in which light is emitted from the display device 10 (i.e., a third direction DR3), the color filter layer 220 may be disposed on the color conversion layer 150, and the second supporting substrate 210 may be disposed on the color filter layer 220. Thus, light emitted from the light-emitting elements LE of the element layer 130 may pass through the color conversion layer 150, the color filter layer 220, and the second supporting substrate 210 to be emitted externally.

The color filter layer 220 may include the first filter sections 221, which are disposed in the first emission areas EA1 and transmit light in the first wavelength range, the second filter sections 222, which are disposed in the second emission areas EA2 and transmit light in the second wavelength range, the third filter sections 223, which are disposed in the third emission areas EA3 and transmit light in the third wavelength range, and the light-blocking section 224, which is disposed in the non-emission area NEA and blocks light.

The first filter sections 221, the second filter sections 222, and the third filter sections 223 may each include a colorant such as a dye or pigment. The colorant may be a material that absorbs light in wavelength ranges other than a predetermined range.

That is, the first filter sections 221 may transmit light in the first wavelength range by including a colorant that absorbs light in wavelength ranges other than the first wavelength range.

The second filter sections 222 may transmit light in the second wavelength range by including a colorant that absorbs light in wavelength ranges other than the second wavelength range.

The third filter sections 223 may transmit light in the third wavelength range by including a colorant that absorbs light in wavelength ranges other than the third wavelength range.

The light-blocking section 224 may include a stacked structure of two or more of the first filter sections 221, the second filter sections 222, and the third filter sections 223.

In an alternative embodiment, the light-blocking section 224 may include a material that absorbs light, such as a black matrix material.

The light recycling components LRC disposed in the first margin areas MGA1 and the second margin areas MGA2 may overlap with the light-blocking section 224 in the non-emission area NEA. This may reduce color mixing or light leakage caused by the light recycling components LRC.

The filter capping layer 230 may cover the color filter layer 220 and may include an inorganic insulating material.

The display device 10 may further include a low-refractive-index layer, which is disposed between the color filter layer 220 and the color conversion layer 150. The low-refractive-index layer may include an organic material with a refractive index of about 1.1 to about 1.4.

In an embodiment, the low-refractive-index layer may be disposed on the color conversion capping layer 160 or on the filter capping layer 230, for example.

The display device 10 may further include the filling layer 300, which is disposed between the first and second substrates 100 and 200.

The filling layer 300 may fill the space between the first and second substrates 100 and 200.

The filling layer 300 may be disposed between the color conversion capping layer 160 of the first substrate 100 and the filter capping layer 230 of the second substrate 200.

The filling layer 300 may include an organic material with light-transmitting and adhesive properties.

In an embodiment, the filling layer 300 may include a silicon (Si)-based organic material or epoxy-based organic material, for example.

As described above, since the first color conversion sections 151 are disposed in both the first emission areas EA1 and the first margin areas MGA1, and the second color conversion sections 152 are disposed in both the second emission areas EA2 and the second margin areas MGA2, the widths of the first emission areas EA1 and the second emission areas

EA2 are not limited by the margin of the ejection device. This may be advantageous for achieving a relatively high resolution in the display device 10.

Additionally, as illustrated in FIG. 9, the display device 10 includes the light recycling components LRC, which are disposed in the first margin areas MGA1 and the second margin areas MGA2.

In an embodiment, the light recycling components LRC may include the reflective layer RFL.

Consequently, some of the light emitted from the light-emitting elements LE and introduced into the first margin areas MGA1 and the second margin areas MGA2 may be reflected by the reflective layer RFL and the reflective walls 1542 due to differences in refractive index at the interfaces and may thus be reused as light RCL emitted into the first emission areas EA1 and the second emission areas EA2.

Therefore, the light emission efficiency in the first emission areas EA1 and the second emission areas EA2 may be improved, which may enhance the brightness of the display device 10.

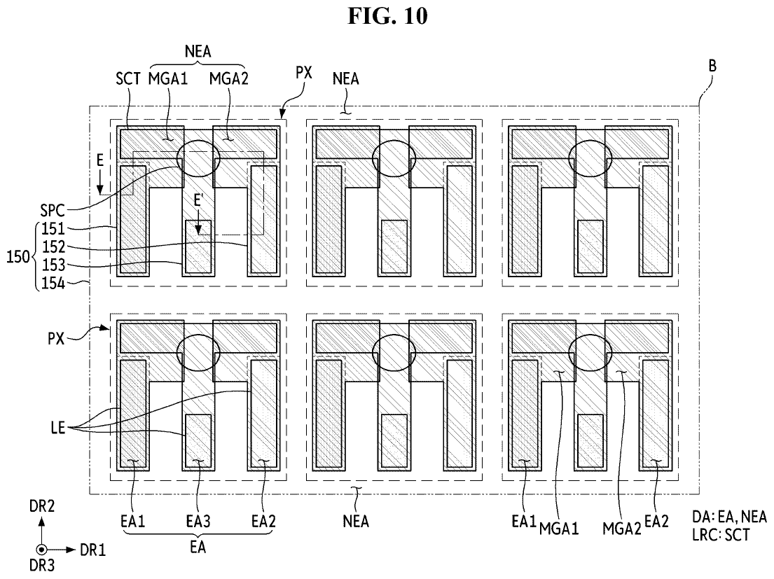

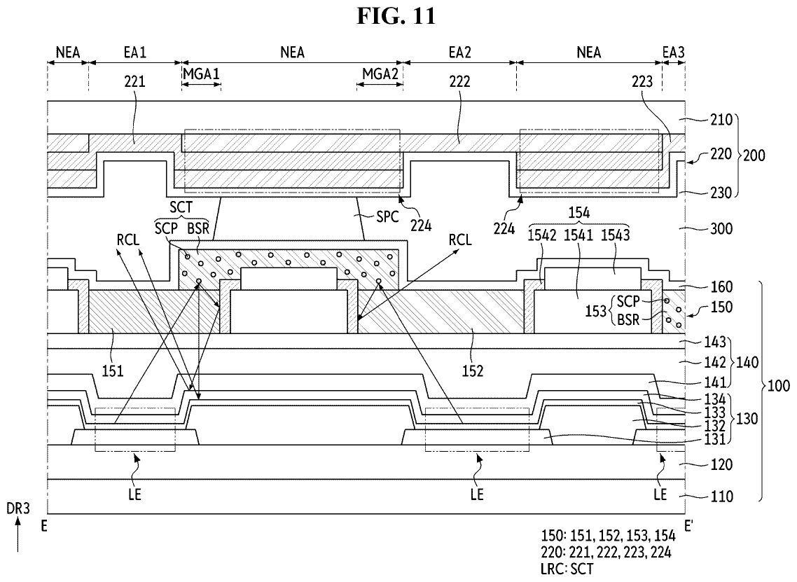

FIG. 10 is a plan view illustrating an embodiment of a color conversion layer, in portion B of FIG. 1, of a display device according to the disclosure. FIGS. 11, 12, 13, and 14 are cross-sectional views taken along line E-E′ of FIG. 10.

A display device 10 of FIG. 10 is substantially the same as the display device 10 of FIG. 6, except that light recycling components LRC include scattering sections SCT instead of a reflective layer RFL, and thus, redundant descriptions will hereinafter be omitted.

Referring FIG. 10, the scattering sections SCT may be disposed in first margin areas MGA1 and second margin areas MGA2.

The scattering sections SCT may overlap with portions of partition sections 154 between first color conversion sections 151 and second color conversion sections 152.

In an embodiment, the scattering sections SCT may be connected to light transmission sections 153 of third emission areas EA3, for example.

Referring to FIG. 11, light recycling components LRC may include the scattering sections SCT, which are disposed on the first color conversion sections 151 of the first margin areas MGA1 and the second color conversion sections 152 of the second margin areas MGA2.

The scattering sections SCT may include a base resin BSR, which has light-transmitting properties, and scattering particles SCP, which are dispersed in the base resin BSR.

The light transmission sections 153 may be provided together with the scattering sections SCT. In other words, the light transmission sections 153 and the scattering sections SCT may both include the base resin BSR and the scattering particles SCP, which are dispersed in the base resin BSR.

Consequently, some of the light emitted from light-emitting elements LE and introduced into the first margin areas MGA1 and the second margin areas MGA2 may be reflected by the scattering particles SCP due to the difference in refractive index at the interfaces RFL and may thus be reused as light RCL emitted into first emission areas EA1 and second emission areas EA2.

Therefore, the light emission efficiency in the first emission areas EA1 and the second emission areas EA2 may be improved, which may enhance the brightness of the display device 10.

In this manner, since no additional stacking or etching process is desired for the arrangement of light recycling components LRC, the manufacturing process of the display device 10 may be prevented from becoming more complex.

Additionally, since the thickness of the scattering sections SCT, which include the base resin BSR that includes or consists of an organic material, is greater than the thickness of the reflective layer RFL, which includes a metal material, the thickness of spacers SPC may be further reduced by the light recycling components LRC.

According to the embodiment of FIGS. 10 and 11, as the scattering sections SCT are arranged through the same process as the light transmission sections 153, a color conversion capping layer 160 may further cover the scattering sections SCT along with a color conversion layer 150.

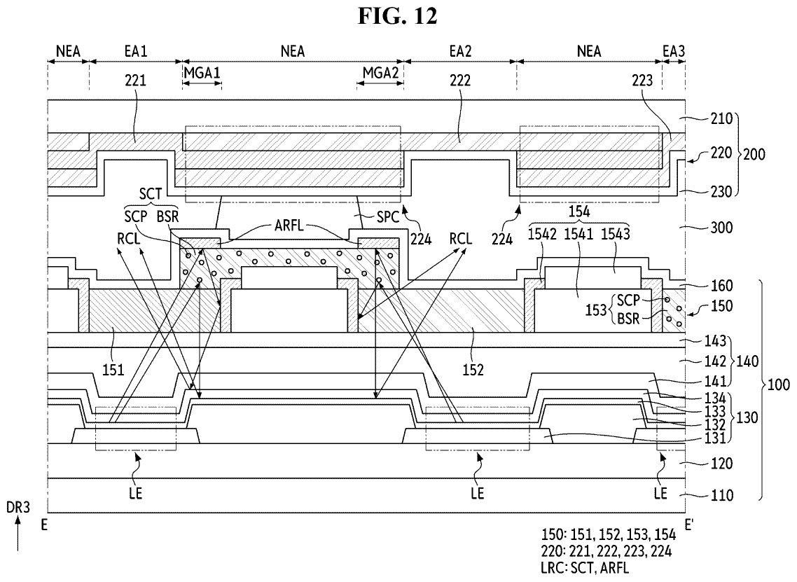

A display device 10 of FIG. 12 is substantially the same as its counterpart of FIGS. 10 and 11, except that light recycling components LRC further include an additional reflective layer ARFL, which is disposed on scattering sections SCT and reflects light, and thus, redundant descriptions will hereinafter be omitted.

In this case, a color conversion capping layer 160 may further cover the additional reflective layer ARFL along with a color conversion layer 150 and the scattering sections SCT. The additional reflective layer ARFL may include a reflective metal material.

In this manner, as the amount of light reflected from first margin areas MGA1 and second margin areas MGA2 increases due to the additional reflective layer ARFL, the amount of reusable light may be increased.

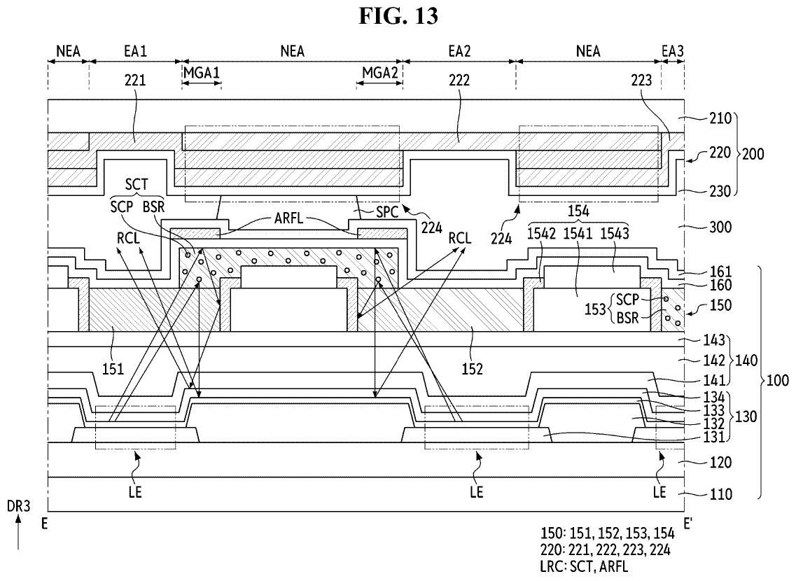

A display device 10 of FIG. 13 is substantially the same as its counterpart of FIG. 12, except that an additional reflective layer ARFL is disposed not on scattering sections SCT but on a color conversion capping layer 160 and is covered by an additional capping layer 161, and thus, redundant descriptions will hereinafter be omitted.

In this manner, the peeling of the additional reflective layer ARFL may be reduced.

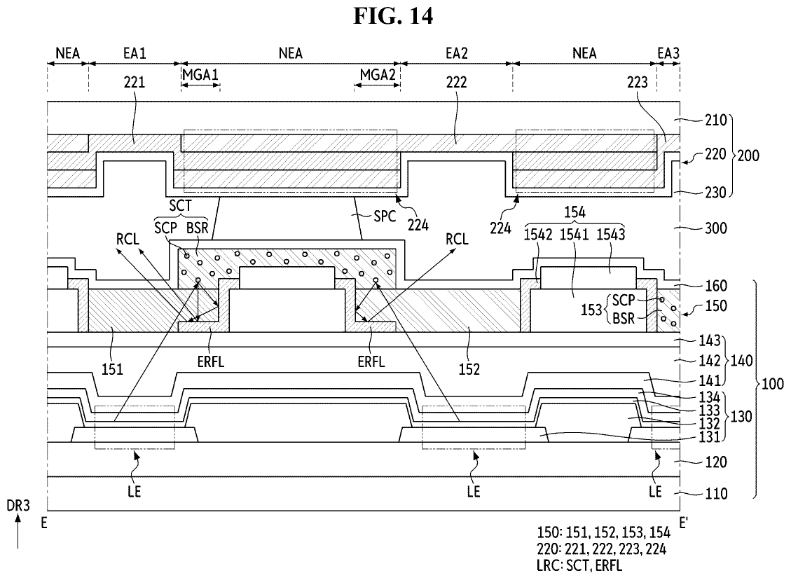

The display device 10 of FIG. 14 is substantially the same as its counterpart of FIGS. 10 and 11, except that light recycling components LRC include an extended reflective layer ERFL, which extends from reflective walls 1542, and thus, redundant descriptions will hereinafter be omitted.

The extended reflective layer ERFL may be disposed on an encapsulation layer 140 in first margin areas MGA1 and second margin areas MGA2 and may extend from reflective walls 1542.

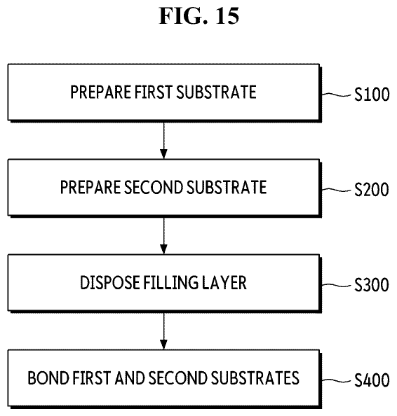

In this manner, as light reflected by scattering particles SCP of scattering sections SCT is further reflected by the extended reflective layer ERFL, the amount of reusable light may be increased. As a result, the brightness of the display device 10 may be further improved. FIG. 15 is a flowchart illustrating an embodiment of a method of manufacturing a

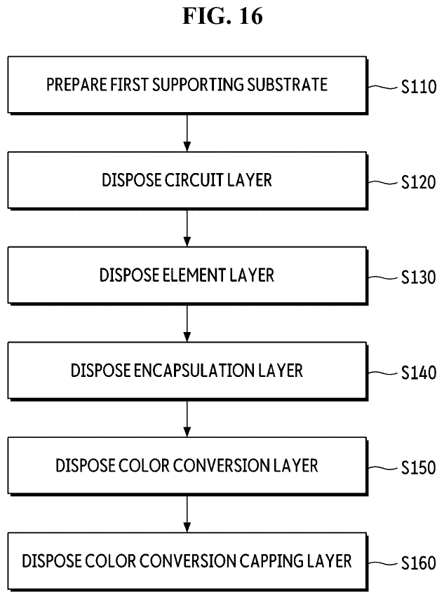

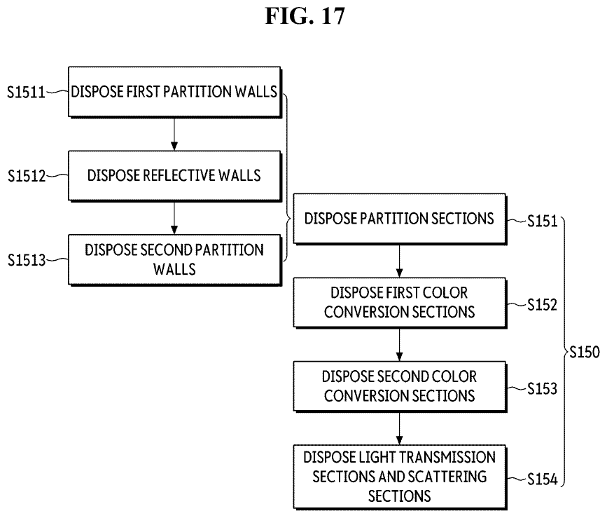

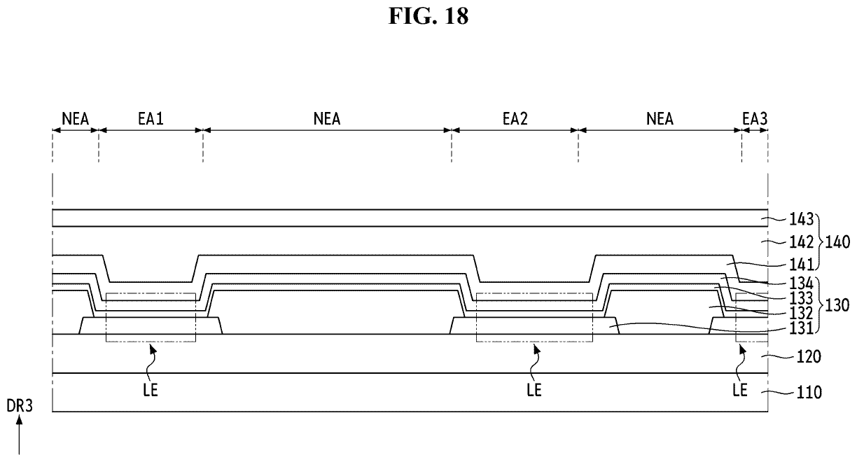

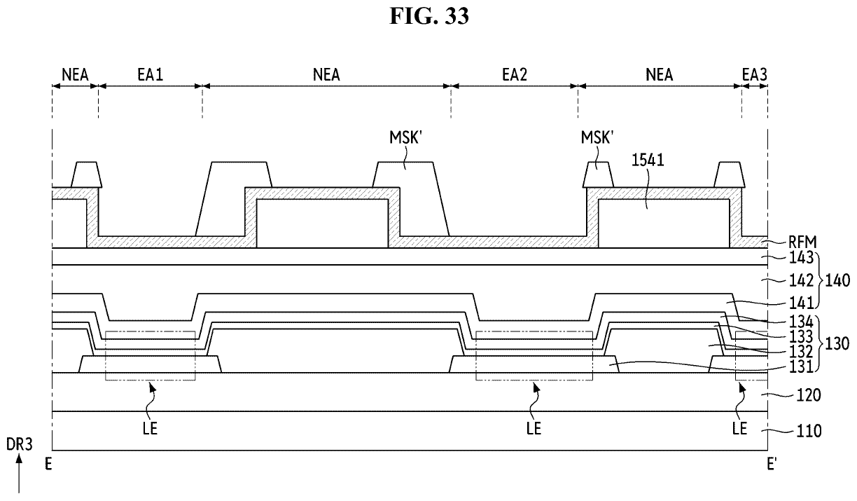

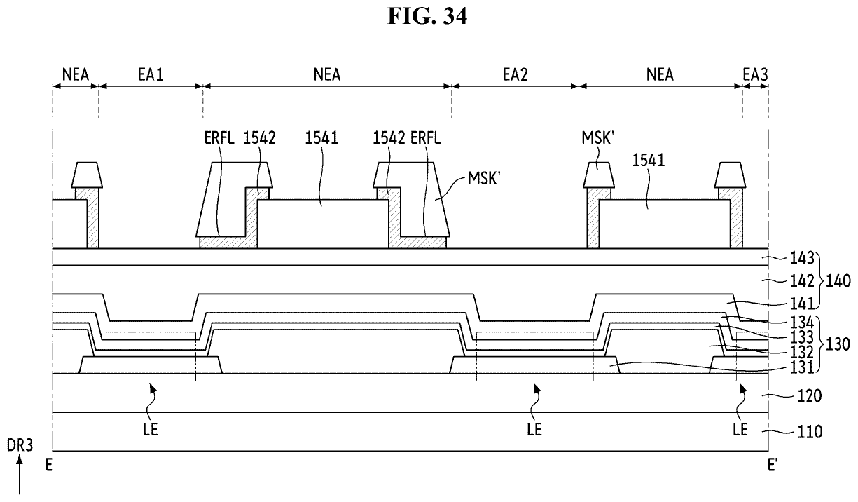

display device according to the disclosure. FIG. 16 is a flowchart illustrating the operation of preparing a first substrate of FIG. 15. FIG. 17 is a flowchart illustrating the operation of disposing a color conversion layer of FIG. 16. FIGS. 18, 19, 20, 21, 22, 23, 24, 25, 26, 27, 28, 29, 30, 31, and 32 are cross-sectional views illustrating some of the operations depicted in FIGS. 15, 16, and 17, in the embodiment of FIG. 11. FIGS. 33 and 34 are cross-sectional views illustrating some of the operations depicted in FIG. 17, in the embodiment of FIG. 14.

Referring to FIG. 15, the method of manufacturing a display device 10 in an embodiment of the disclosure may include the operations of preparing a first substrate 100 (S10), preparing a second substrate 200 (S20), disposing a filling layer 300 on the first substrate 100 or the second substrate 200 (S30), and bonding the first substrate 100 to the second substrate 200

(S40).

Referring to FIG. 16, the operation (S10) of preparing the first substrate 100 may include the operations of preparing a first supporting substrate 110, which includes emission areas EA arranged in parallel and a non-emission area NEA between the emission areas EA (S110), disposing a circuit layer 120 on the first supporting substrate 110 (S120), disposing an element layer 130 on the circuit layer 120 (S130), disposing an encapsulation layer 140 on the element layer 130 (S140), disposing a color conversion layer 150 on the encapsulation layer 140 (S150), and disposing a color conversion capping layer 160, which covers the color conversion layer 150 (S160).

As described above with reference to FIGS. 6, 9, and 10 through 14, after the operation (S150) of disposing the color conversion layer 150, the color conversion layer 150 includes light recycling components LRC, which are disposed in parts of the non-emission area NEA.

As described above with reference to FIGS. 3, 6, and 10, the emission areas EA may include first emission areas EA1, which emit light in a first wavelength range, second emission areas EA2, which emit light in a second wavelength range lower than the first wavelength range, and third emission areas EA3, which emit light in a third wavelength range lower than the second wavelength range.

Further, the non-emission area NEA may include first margin areas MGA1, which are connected to parts of the first emission areas EA1, and second margin areas MGA2, which are connected to parts of the second emission areas EA2.

Additionally, as described above with reference to FIGS. 6, 9, and 10 through 14, the element layer 130 may include light-emitting elements LE, which are disposed in the emission areas EA.

The light-emitting elements LE may emit light in a fourth wavelength range lower than the third wavelength range.

Referring to FIG. 17, the operation (S150) of disposing a color conversion layer 150 may include the operations of disposing partition sections 154 across the entirety of the non-emission area NEA except for the first margin areas MGA1 and the second margin areas MGA2 (S151), disposing first color conversion sections 151, which convert light in the fourth wavelength range into light in the first wavelength range, on the first emission areas EA1 and the first margin areas MGA1 (S152), disposing second color conversion sections 152, which convert light in the fourth wavelength range into light in the second wavelength range, on the second emission areas EA2 and the second margin areas MGA2 (S153), and disposing light transmission sections 153, which transmit and scatter light in the fourth wavelength range, on the third emission areas EA3 (S154).

The operation (S151) of disposing the partition section 154 may include the operations of disposing first partition walls 1541 across the entirety of the non-emission area NEA except for the first margin areas MGA1 and the second margin areas MGA2 (S1511), disposing reflective walls 1542, which reflect light, on the sides of the first partition walls 1541 (S1512), and disposing second partition walls 1543, which have hydrophobic properties, on at least parts of the top surfaces of the first partition walls 1541 (S1513).

As illustrated in FIG. 18, in the operation (S110) of preparing a first supporting substrate 110, the first supporting substrate 110 may be prepared in the form of a flat plate including a display area DA and a non-display area NDA.

The display area DA may include emission areas EA and a non-emission area NEA.

In the operation (S120) of disposing the circuit layer 120, the circuit layer 120, which includes the emissive pixel drivers EPD of FIG. 3, may be disposed on the first supporting substrate 110.

Each of the emissive pixel drivers EPD may include two or more transistors.

In the operation (S130) of disposing the element layer 130, the element layer 130 may include anode electrodes 131, which are disposed in the emission areas EA, a pixel-defining layer 132, which is disposed in the non-emission area NEA and covers the edges of the anode electrodes 131, light-emitting layers 133, which are disposed on the anode electrodes 131 and the pixel-defining layer 132, and a cathode electrode 134, which is disposed on the light-emitting layers 133.

The light-emitting elements LE may be disposed in the emission areas EA and may include a structure where the light-emitting layers 133 are interposed between the anode electrodes 131 and the cathode electrode 134 that face each other.

In the operation (S140) of disposing an encapsulation layer 140, the encapsulation layer 140 may include a first encapsulation layer 141, which covers the element layer 130 and includes an inorganic insulating material, a second encapsulation layer 142, which is disposed on the first encapsulation layer 141 and includes an organic insulating material, and a third encapsulation layer 143, which is disposed on the second encapsulation layer 142 and includes an inorganic insulating material.

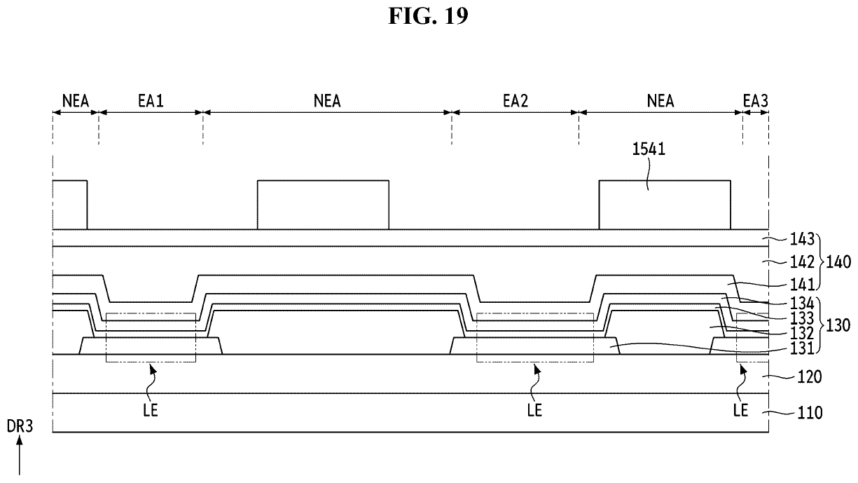

As illustrated in FIG. 19, in the operation (S1511) of disposing the first partition walls 1541, which is a sub-operation of the operation (S151) of disposing the partition sections 154, the first partition walls 1541 may be disposed by selectively etching the organic material on the encapsulation layer 140. The first partition walls 1541 may be formed in the first emission areas EA1, the first margin areas MGA1, the second emission areas EA2, the second margin areas MGA2, and the third emission areas EA3 and may include apertures exposing the encapsulation layer 140.

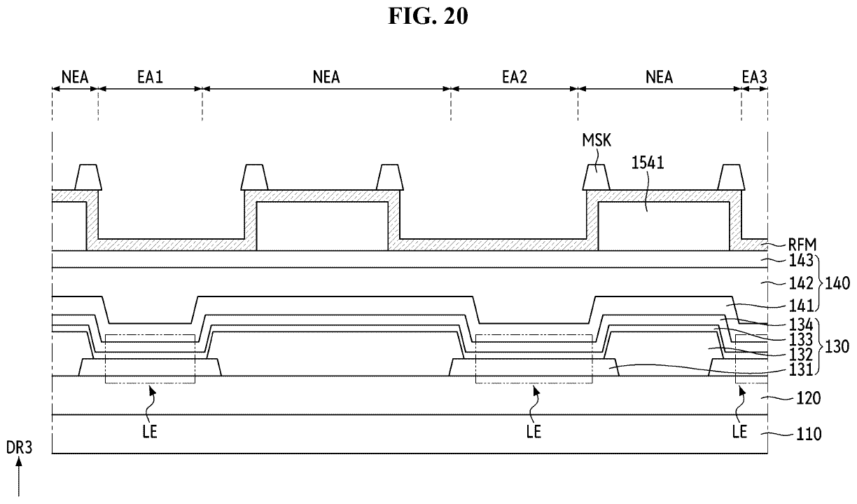

Referring to FIG. 20, the operation (S1512) of disposing the reflective walls 1542 may include the operations of disposing a metal material layer RFM, which has reflectivity, on the encapsulation layer 140 and covers the first partition walls 1541, and disposing a mask MSK on parts of the metal material layer RFM. The mask MSK may overlap with the edges of the top surfaces of the first partition walls 1541 and the sides of the first partition walls 1541.

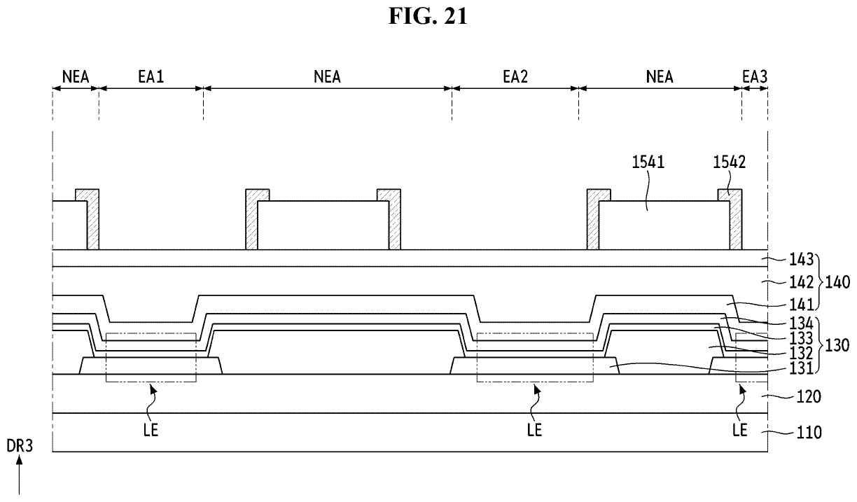

Referring to FIG. 21, the operation (S1512) of disposing the reflective walls 1542 may further include selectively etching the metal material layer RFM using the mask MSK. As a result, the reflective walls 1542 may be disposed on the sides of the first partition walls 1541.

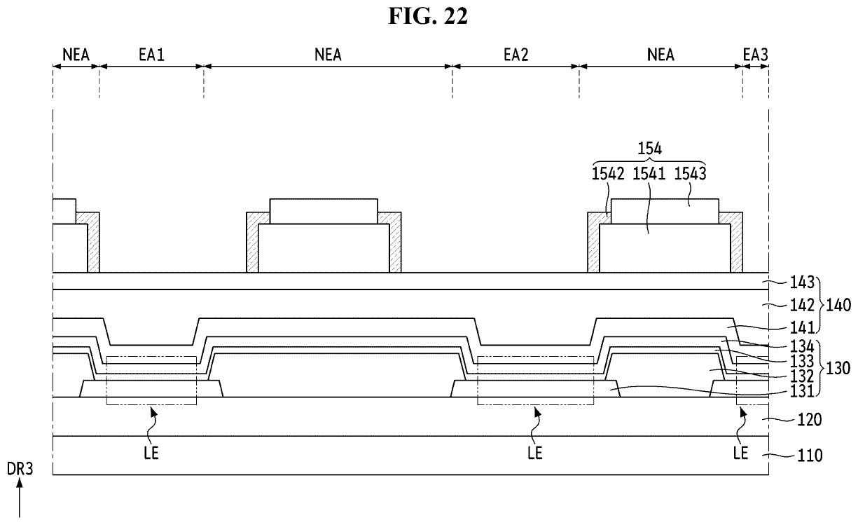

Referring to FIG. 22, the operation (S1513) of disposing the second partition walls 1543 may include exposing and developing parts of the organic material that covers the first partition walls 1541 and the reflective walls 1542, specifically the parts disposed on the first partition walls 1541.

During the exposure of the organic material, hydrophobic substances in the organic material may react to light and flow to the surfaces. Consequently, during the development of the organic material, second partition walls 1543 with hydrophobic surfaces may be formed.

As a result, the partition sections 154 including the first partition walls 1541, the reflective walls 1542, and the second partition walls 1543 may be disposed on the entirety of the non-emission area NEA except for the first margin areas MGA1 and the second margin areas MGA2.

Referring to FIG. 23, the operation S152 of disposing the first color conversion sections 151 may include ejecting a first ink material INK1 onto at least parts of the first emission areas EA1 and at least parts of the first margin areas MGA1 using a dispensing device NZ that moves while facing the display area DA.

The first ink material INK1 may include a liquid base resin, first ink that converts light in the fourth wavelength range into light in the first wavelength range, and scattering particles.

At this time, due to the hydrophobic surfaces of the second partition walls 1543, the first ink material INK1 may be retained in the spaces overlapping with and surrounded by the partition sections 154 in the first emission areas EA1 and the first margin areas MGA1.

Referring to FIG. 24, the operation S152 of disposing the first color conversion sections 151 may include the operation of disposing the first color conversion sections 151 by curing the first ink material INK1 retained in the first emission areas EA1 and the first margin areas MGA1.

Thereafter, the operation (S153) of disposing the second color conversion sections 152 may include ejecting a second ink material INK2 onto at least parts of the second emission areas EA2 and at least parts of the second margin areas MGA2 using a dispensing device NZ that moves while facing the display area DA.

The second ink material INK2 may include a liquid base resin, second ink that converts light in the fourth wavelength range into light in the second wavelength range, and scattering particles.

At this time, due to the hydrophobic surfaces of the second partition walls 1543, the second ink material INK2 may be retained in the spaces overlapping with and surrounded by the partition sections 154 in the second emission areas EA2 and the second margin areas MGA2.

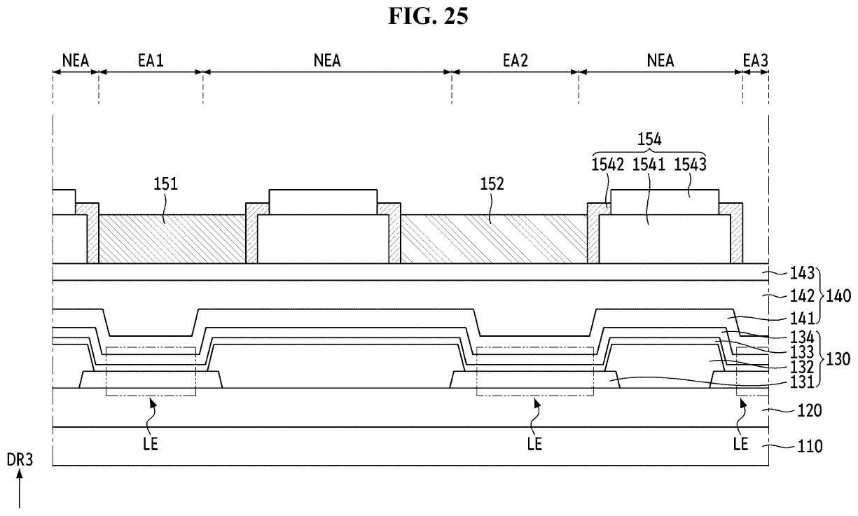

Referring to FIG. 25, the operation (S153) of disposing the second color conversion sections 152 may include forming the second color conversion sections 152 by curing the second ink material INK2 retained in the second emission areas EA2 and the second margin areas MGA2.

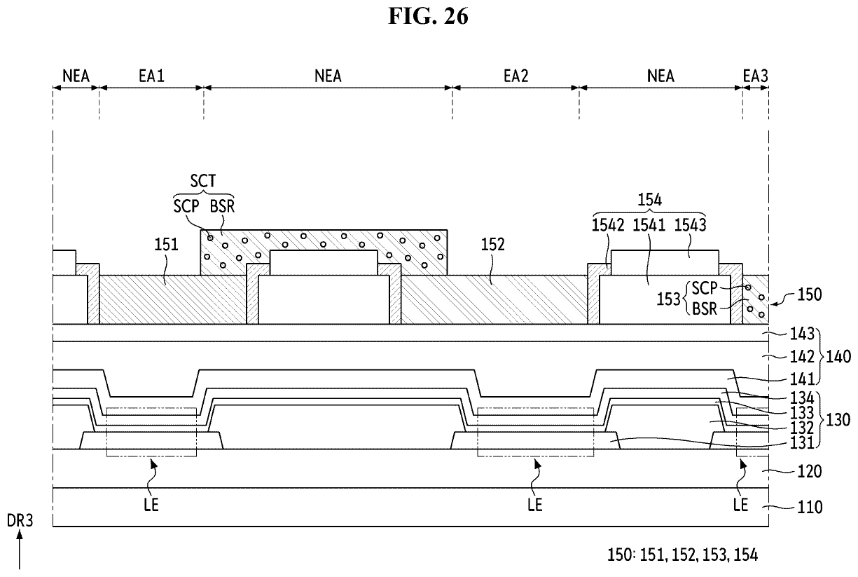

Referring to FIG. 26, in the operation (S154) of disposing the light transmission sections 153, the light transmission sections 153 and the scattering sections SCT may be disposed by selectively etching an organic material with transparency that covers the encapsulation layer 140, the first color conversion sections 151, the second color conversion sections 152, and the partition sections 154.

The light transmission sections 153 and the scattering sections SCT may each include a base resin BSR and scattering particles SCP, which are dispersed in the base resin BSR.

The light transmission sections 153 may be retained in the spaces overlapping with and surrounded by the partition sections 154 in the third emission areas EA3.

The scattering sections SCT may be disposed on the first color conversion sections 151 of the first margin areas MGA1 and the second color conversion sections 152 of the second margin areas MGA2.

As a result, the color conversion layer 150, which includes the first color conversion sections 151, the second color conversion sections 152, the light transmission sections 153, and the partition sections 154, and the scattering sections SCT may be disposed.

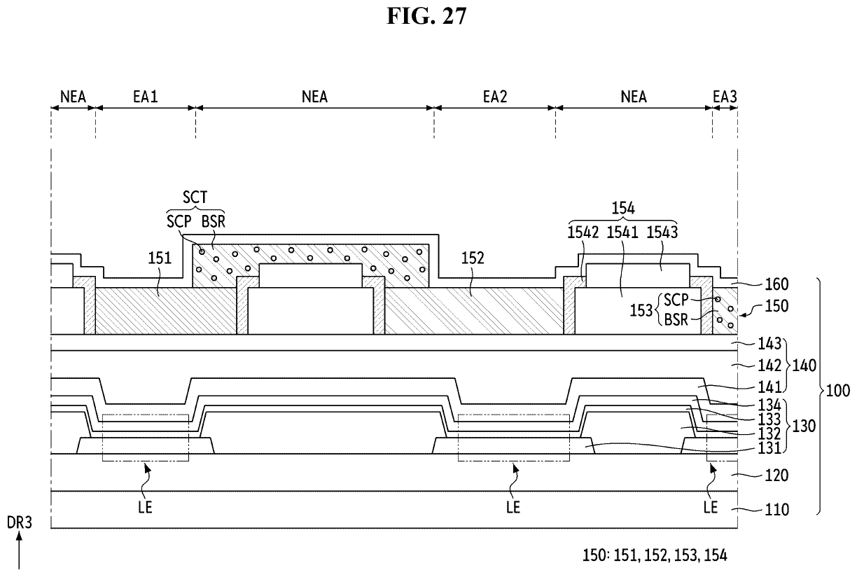

Referring to FIG. 27, in the operation (S160) of disposing the color conversion capping layer 160, the color conversion capping layer 160 may be disposed by laminating an inorganic insulating material to cover the color conversion layer 150.

The color conversion capping layer 160 may also cover the scattering sections SCT.

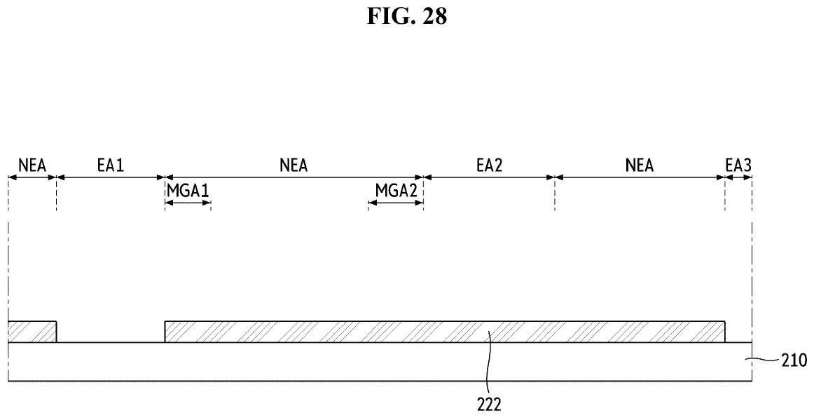

Referring to FIG. 28, in the operation (S210) of preparing a second supporting substrate 210, which is a sub-operation of the operation (S200) of preparing the second substrate 200, the second supporting substrate 210 may be prepared in the form of a flat plate including a display area DA and a non-display area NDA.

Referring to FIGS. 28, 29, and 30, the operation (S220) of disposing the color filter layer 220 may include the operations of disposing second filter sections 222, which transmit light in the second wavelength range, on the second emission areas EA2 and the non-emission area NEA, disposing first filter sections 221, which transmit light in the first wavelength range, on the first emission areas EA1 and the non-emission area NEA, and disposing third filter sections 223, which transmit light in the third wavelength range, on the third emission areas EA3 and the non-emission area NEA.

Referring to FIG. 28, in the operation of disposing the second filter sections 222, the second filter sections 222 may be disposed on the second supporting substrate 210 in the second emission areas EA2 and the non-emission area NEA.

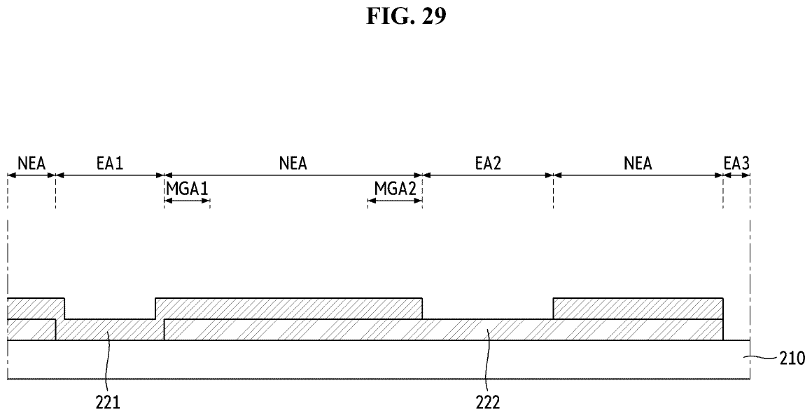

Referring to FIG. 29, in the operation of disposing the first filter sections 221, some of the first filter sections 221 may be disposed on the second supporting substrate 210 in the first emission areas EA1, and other first filter sections 221 may be disposed on the second filter sections 222 in the non-emission area NEA.

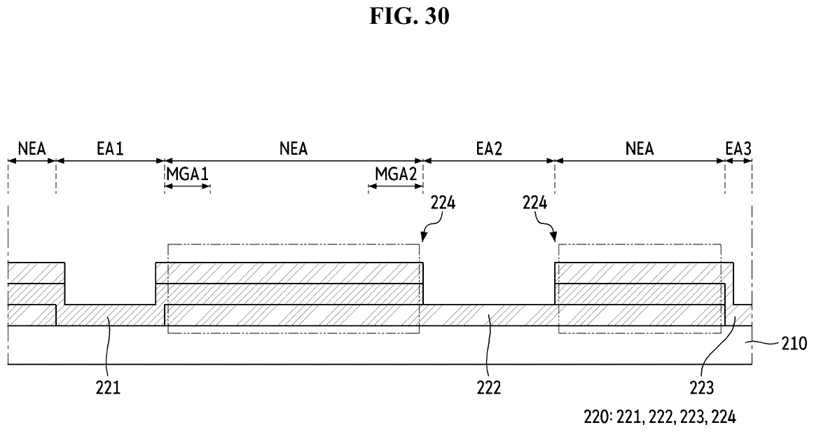

Referring to FIG. 30, in the operation of disposing the third filter sections 223, some of the third filter sections 223 may be disposed on the second supporting substrate 210 in the third emission areas EA3, and other third filter sections 223 may be disposed on the first filter sections 221 in the non-emission area NEA.

Consequently, the light-blocking section 224, which is formed by laminating the second filter sections 222, the first filter sections 221, and the third filter sections 223, may be disposed in the non-emission area NEA. The color filter layer 220, including the first filter sections 221, the second filter sections 222, the third filter sections 223, and the light-blocking section 224, may be disposed.

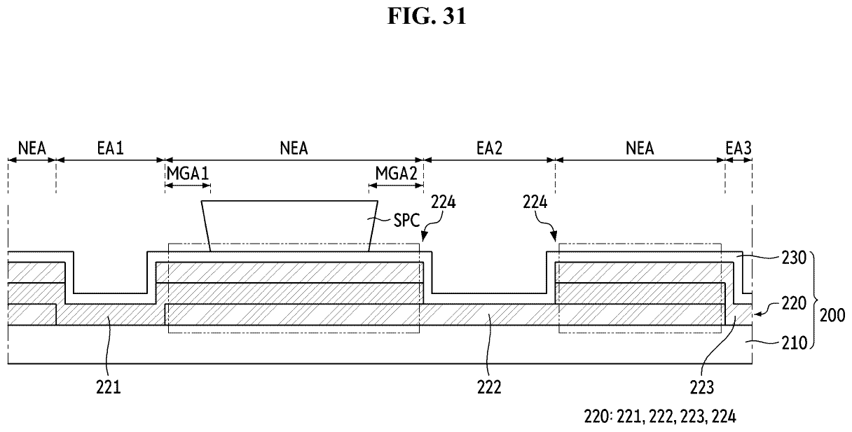

Referring to FIG. 31, the operation (S200) of disposing the second substrate 200 may include the operation of disposing a filter capping layer 230.

In the operation of disposing the filter capping layer 230, the filter capping layer 230 may be disposed by laminating an inorganic insulating material to cover the color filter layer 220.

Additionally, the operation (S200) of disposing the second substrate 200 may further include the operation of disposing spacers SPC, which are spaced apart from one another, on the filter capping layer 230.

In the operation of disposing the spacers SPC, the spacers SPC, which are spaced apart from each other, may be disposed in the non-emission area NEA by selectively etching the organic material on the filter capping layer 230.

Each of the spacers SPC may overlap with one or more of the first margin areas MGA1 and the second margin areas MGA2.

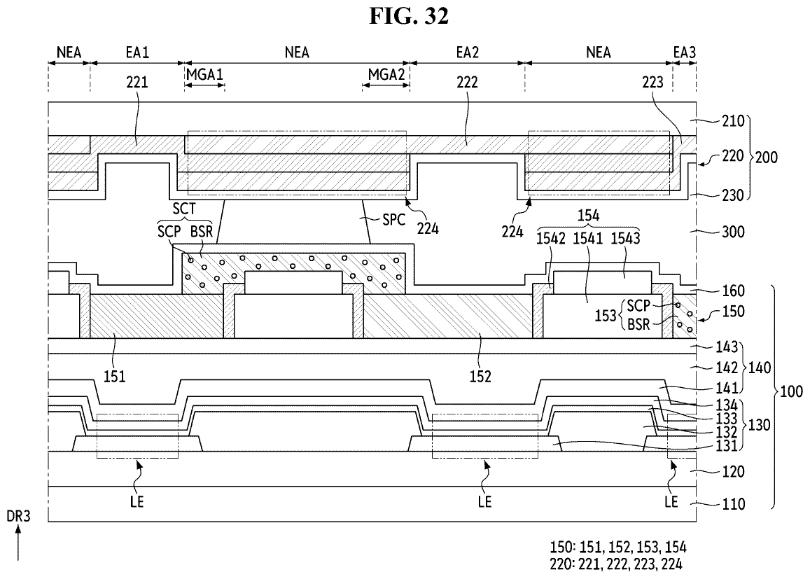

Referring to FIG. 32, in the operation (S400) of bonding the first and second substrates 100 and 200, followed by the operation (S300) of disposing the filling layer 300 on the first or second substrate 100 or 200, the first and second substrates 100 and 200 may be aligned such that the color conversion layer 150 of the first substrate 100 and the color filter layer 220 of the second substrate 200 may face each other with the filling layer 300 interposed therebetween. The filling layer 300 may be widely spread by reducing the gap between the first and second substrates 100 and 200. Then, the first substrate 100 and the second substrate 200 may be bonded together by the filling layer 300 and the sealing layer 400 of FIG. 2.

Referring to FIG. 33, in the operation (S1512) of disposing the reflective walls 1542 during the manufacture of the display device 10 of FIG. 14, the mask MSK′ on the metal material layer RFM may overlap not only with the edges of the top surfaces of the first partition walls 1541 and the sides of the first partition walls 1541, but also with the first margin areas MGA1 and the second margin areas MGA2.

Thus, as illustrated in FIG. 34, by selectively etching the metal material layer RFM using the mask MSK′, the reflective walls 1542 may be disposed on the sides of the first partition walls 1541, and an extended reflective layer ERFL may be disposed on the encapsulation layer 140 of the first margin areas MGA1 and the second margin areas MGA2.

Although embodiments of the invention have been described with reference to the attached drawings, it will be understood by those of ordinary skill in the art that the invention may be embodied in other predetermined forms without departing from the spirit or essential characteristics of the invention. Therefore, the described embodiments are to be considered in all respects as illustrative and not restrictive.

What is claimed is:

1. A display device comprising:
a first substrate including:
a first supporting substrate, which includes emission areas arranged in parallel and a non-emission area between the emission areas;
an element layer, which is disposed on the first supporting substrate and includes light-emitting elements disposed in the emission areas;
an encapsulation layer, which is disposed on the element layer, and
a color conversion layer, which is disposed on the encapsulation layer and converts a wavelength range of light emitted from some of the light-emitting elements, the color conversion layer including:
light recycling components, which are disposed in parts of the non-emission area; and
a second substrate facing the first substrate.

2. The display device of claim 1, wherein
the emission areas include:
first emission areas, which emit light in a first wavelength range;
second emission areas, which emit light in a second wavelength range lower than the first wavelength range; and
third emission areas, which emit light in a third wavelength range lower than the second wavelength range,
the non-emission area includes:
first margin areas, which are connected to parts of the first emission areas; and
second margin areas, which are connected to parts of the second emission areas,
the light-emitting elements emit light in a fourth wavelength range lower than the third wavelength range,
the color conversion layer includes:
first color conversion sections, which are disposed in the first emission areas and the first margin areas and convert light in the fourth wavelength range into light in the first wavelength range;
second color conversion sections, which are disposed in the second emission areas and the second margin areas and convert light in the fourth wavelength range into light in the second wavelength range;
light transmission sections, which are disposed in the third emission areas and transmit and scatter light in the fourth wavelength range; and
partition sections, which are disposed between the first color conversion sections, the second color conversion sections, and the light transmission sections, and
the light recycling components are disposed in the first margin areas and the second margin areas.

3. The display device of claim 2, wherein the partition sections include:
first partition walls, which are disposed between the first color conversion sections, the second color conversion sections, and the light transmission sections;
reflective walls, which cover sides of the first partition walls and reflect light; and
second partition walls, which are disposed on the first partition walls and have hydrophobic properties.

4. The display device of claim 3, wherein
the second substrate includes:
a second supporting substrate, which faces the first substrate and includes the emission areas and the non-emission area;
a color filter layer, which is disposed on one surface of the second supporting substrate, and a filter capping layer, which covers the color filter layer,
the color filter layer includes:
first filter sections, which are disposed in the first emission areas and transmit light in the first wavelength range;
second filter sections, which are disposed in the second emission areas and transmit light in the second wavelength range;
third filter sections, which are disposed in the third emission areas and transmit light in the third wavelength range; and
a light-blocking section, which is disposed in the non-emission area and blocks light, and
the light recycling components overlap with the light-blocking section.

5. The display device of claim 4, further comprising:
spacers disposed between the first substrate and the second substrate; and
a filling layer disposed between the first and second substrates,
wherein
the first substrate further includes a color conversion capping layer, which covers the color conversion layer,
the spacers and the filling layer are disposed between the color conversion capping layer and the filter capping layer, and
the spacers overlap with one or more of the first margin areas and the second margin areas.

6. The display device of claim 4, wherein the light recycling components include a reflective layer, which is disposed on the first color conversion sections in the first margin areas and on the second color conversion sections in the second margin areas and reflects light.

7. The display device of claim 4, wherein
the light recycling components include scattering sections, which are disposed on the first color conversion sections in the first margin areas and on the second color conversion sections in the second margin areas and scatter light,
the scattering sections overlap with parts of the partition sections between the first color conversion sections and the second color conversion sections, and
the scattering sections include a base resin, which have light transmission properties, and scattering particles, which are dispersed in the base resin.

8. The display device of claim 7, wherein the light transmission sections are provided along with the scattering sections and include the base resin and the scattering particles.

9. The display device of claim 7, wherein the light recycling components further include an additional reflective layer, which is disposed on the scattering sections and reflect light.

10. The display device of claim 4, wherein the light recycling components include an extended reflective layer, which extends from the reflective walls and is disposed on the encapsulation layer.

11. The display device of claim 4, wherein
the first substrate further includes a circuit layer disposed on the first supporting substrate and including emissive pixel drivers electrically connected to the light-emitting elements,
the element layer is disposed on the circuit layer,
the element layer includes:
anode electrodes, which are disposed in the emission areas, a pixel-defining layer, which is disposed in the non-emission area and covers edges of the anode electrodes;
light-emitting layers, which are disposed on the anode electrodes and the pixel-defining layer; and
a cathode electrode, which is disposed on the light-emitting layers, and
each of the light-emitting elements includes a structure in which the light-emitting layers are interposed between the anode electrodes and the cathode electrode which face each other.

12. A method of manufacturing a display device, the method comprising:
preparing a first substrate;
preparing a second substrate;
disposing a filling layer on the first and second substrates; and
bonding the first substrate to the second substrate,
wherein
the preparing the first substrate includes:
preparing a first supporting substrate, which includes emission areas arranged in parallel and a non-emission area between the emission areas;
disposing a circuit layer on the first supporting substrate;
disposing an element layer, which includes light-emitting elements in the emission areas, on the circuit layer;
disposing an encapsulation layer on the element layer;
disposing a color conversion layer on the encapsulation layer; and
disposing a color conversion capping layer, which covers the color conversion layer, and
after the disposing the color conversion layer, the color conversion layer includes light recycling components, which are disposed in parts of the non-emission area.

13. The method of claim 12, wherein
in the preparing the first supporting substrate, the emission areas include first emission areas, which emit light in a first wavelength range, second emission areas, which emit light in a second wavelength range lower than the first wavelength range, and third emission areas, which emit light in a third wavelength range lower than the second wavelength range, and the non-emission area includes first margin areas, which are connected to parts of the first emission areas, and second margin areas, which are connected to parts of the second emission areas,
in the disposing the element layer, the light-emitting elements emit light in a fourth wavelength range lower than the third wavelength range,
the disposing the color conversion layer includes:
disposing partition sections on an entirety of the non-emission area except for the first margin areas and the second margin areas; disposing first color conversion sections, which convert light in the fourth wavelength range into light in the first wavelength range, on the first emission areas and the first margin areas;
disposing second color conversion sections, which convert light in the fourth wavelength range into light in the second wavelength range, on the second emission areas and the second margin areas; and
disposing light transmission sections, which transmit and scatter light in the fourth wavelength range, on the third emission areas.

14. The method of claim 13, wherein
after the disposing the light transmission sections, the partition sections are disposed between the first color conversion sections, the second color conversion sections, and the light transmission sections, and
the disposing the partition sections includes:
disposing first partition walls on the entirety of the non-emission area except for the first margin areas and the second margin areas;
disposing reflective walls, which reflect light, on sides of the first partition walls; and
disposing second partition walls, which have hydrophobic properties, on at least parts of top surfaces of the first partition walls.

15. The method of claim 14, wherein
in the disposing the reflective walls, an extended reflective layer, which extends from the reflective walls, is further disposed in the first margin areas and the second margin areas, and
the light recycling components include the extended reflective layer.

16. The method of claim 13, wherein the preparing the second substrate includes: preparing a second supporting substrate, which includes the emission areas and the non-emission area; disposing a color filter layer on one surface of the second supporting substrate; and disposing a filter capping layer covering the color filter layer,
the disposing the color filter layer includes:
disposing second filter sections, which transmit light in the second wavelength range, in the second emission areas and the non-emission area;
disposing first filter sections, which transmit light in the first wavelength range, in the first emission areas and the non-emission area; and
disposing third filter sections, which transmit light in the third wavelength range, in the third emission areas and the non-emission area,
after the disposing the color filter layer, the color filter layer includes a light-blocking section, which has a structure in which the first filter sections, the second filter sections, and the third filter sections overlap with one another, and
after the bonding the first and second substrates, the light recycling components overlap with the light-blocking section.

17. The method of claim 16, wherein
the preparing the second substrate further includes disposing spacers, which are spaced apart from one another, on the filter capping layer,
after the bonding the first substrate to the second substrate, the spacers and the filling layer are disposed between the color conversion capping layer and the filter capping layer, and
the spacers overlap with one or more of the first margin areas and the second margin areas.

18. The method of claim 13, wherein
the disposing the color conversion layer further includes disposing a reflective layer, which reflects light, on the first color conversion sections in the first margin areas and on the second color conversion sections in the second margin areas, after the disposing the light transmission sections, and
the light recycling components include the reflective layer.

19. The method of claim 13, wherein
in the disposing the light transmission sections, scattering sections, which scatter light, are further disposed on the first color conversion sections in the first margin areas and on the second color conversion sections in the second margin areas,
the scattering sections overlap with parts of the partition sections between the first color conversion sections and the second color conversion sections,
the light transmission sections and the scattering sections each include a base resin, which have light transmission properties, and scattering particles, which are dispersed in the base resin, and
the light recycling components include the scattering sections.

20. The method of claim 19, wherein
the disposing the color conversion layer further includes disposing a reflective layer, which reflects light, on the scattering sections, after the disposing the light transmission sections, and
the light recycling components further include the reflective layer.
